(19) United States
(12) Patent Application Publication
(10) Pub. No.: US 2026/0221098 A1
(43) Pub. Date: Jul. 30, 2026

(54) DISPLAY PANEL AND DISPLAY DEVICE

(71) Applicant: Xiamen Tianma Display Technology Co., Ltd., Xiamen (CN)

(72) Inventors: Xingyao ZHOU, Xiamen (CN); Yana GAO, Xiamen (CN); Jian KUANG, Xiamen (CN); Zhiqiang XIA, Xiamen (CN); Kang YANG, Xiamen (CN)

(21) Appl. No.: 19/414,879

(22) Filed: Dec. 10, 2025

(30) Foreign Application Priority Data
Jan. 24, 2025 (CN) 202510116878.X

(51) Int. Cl. G09G 3/3241

(52) U.S. Cl. CPC G09G 3/3241; G09G 2300/0426; G09G 2310/08; G09G 2320/0233; G09G 2320/0242; G09G 2330/021

(57) ABSTRACT

Display panel and display device are provided. The display panel includes pixel circuits, pixel-circuit column groups, and light-emitting elements. The pixel circuit includes driving transistor and first transistor. The pixel circuit at least includes first pixel circuit, second pixel circuit, third pixel circuit, and fourth pixel circuit. The pixel-circuit column group includes first pixel-circuit column, second pixel-circuit column, third pixel-circuit column, and fourth pixel-circuit column. The first pixel-circuit column includes first pixel circuits, the second pixel-circuit column includes second pixel circuits, the third pixel-circuit column includes third pixel circuits, and the fourth pixel-circuit column includes fourth pixel circuits. The first pixel circuit drives first color light-emitting element or third color light-emitting element, the second pixel circuit drives second color light-emitting element, the third pixel circuit drives second color light-emitting element, and the fourth pixel circuit drives third color light-emitting element or first color light-emitting element.

### CROSS-REFERENCE TO RELATED APPLICATION

The present disclosure claims priority of Chinese Patent Application No. 202510116878.X, filed on Jan. 24, 2025, the entire content of which is hereby incorporated by reference.

### FIELD OF THE DISCLOSURE

The present disclosure generally relates to the field of display technology and, more particularly, relates to a display panel and a display device.

### BACKGROUND

An organic light-emitting diode (OLED) has advantages of low power consumption, low cost, self-luminescence, wide viewing angle and fast response speed, and has become a focus of current display research. When an OLED is used in a display panel, a pixel circuit is generally designed to provide driving current for the OLED to drive the OLED to emit light. Changes in the driving current may have a significant impact on brightness of the OLED.

However, in the pixel circuit of an existing OLED display panel, due to fluctuation errors in the fabrication process of the pixel circuits, there may be differences in the driving current of different pixels. When the differences are serious, display color deviation and display mura may appear.

As such, providing a display panel and a display device that may decrease color deviation, weaken mura visual effects, and improve display effects is an urgent technical problem to be solved by those skilled in the art.

### SUMMARY

One aspect of the present disclosure includes a display panel. The display panel includes a plurality of pixel circuits, a plurality of pixel-circuit column groups sequentially arranged along a first direction, and a plurality of light-emitting elements. A pixel circuit of the plurality of pixel circuits includes a driving transistor and a first transistor electrically connected to the driving transistor. The plurality of pixel circuits at least includes a first pixel circuit, a second pixel circuit, a third pixel circuit, and a fourth pixel circuit. A pixel-circuit column group of the plurality of pixel-circuit column groups includes a first pixel-circuit column, a second pixel-circuit column, a third pixel-circuit column, and a fourth pixel-circuit column. The first pixel-circuit column includes a plurality of the first pixel circuits, the second pixel-circuit column includes a plurality of the second pixel circuits, the third pixel-circuit column includes a plurality of the third pixel circuits, and the fourth pixel-circuit column includes a plurality of the fourth pixel circuits. A channel width of the first transistor of the first pixel circuit is different from a channel width of the first transistor of the second pixel circuit, a channel width of the first transistor of the third pixel circuit is different from a channel width of the first transistor of the fourth pixel circuit, the channel width of the first transistor of the first pixel circuit is equal to the channel width of the first transistor of the third pixel circuit, and the channel width of the first transistor of the second pixel circuit is equal to the channel width of the first transistor of the fourth pixel circuit. The plurality of light-emitting elements includes a first color light-emitting element, a second color light-emitting element, and a third color light-emitting element. The first pixel circuit drives the first color light-emitting element or the third color light-emitting element, the second pixel circuit drives the second color light-emitting element, the third pixel circuit drives the second color light-emitting element, and the fourth pixel circuit drives the third color light-emitting element or the first color light-emitting element.

Another aspect of the present disclosure includes a display device. The display device includes a display panel. The display panel includes a plurality of pixel circuits, a plurality of pixel-circuit column groups sequentially arranged along a first direction, and a plurality of light-emitting elements. A pixel circuit of the plurality of pixel circuits includes a driving transistor and a first transistor electrically connected to the driving transistor. The plurality of pixel circuits at least includes a first pixel circuit, a second pixel circuit, a third pixel circuit, and a fourth pixel circuit. A pixel-circuit column group of the plurality of pixel-circuit column groups includes a first pixel-circuit column, a second pixel-circuit column, a third pixel-circuit column, and a fourth pixel-circuit column. The first pixel-circuit column includes a plurality of the first pixel circuits, the second pixel-circuit column includes a plurality of the second pixel circuits, the third pixel-circuit column includes a plurality of the third pixel circuits, and the fourth pixel-circuit column includes a plurality of the fourth pixel circuits. A channel width of the first transistor of the first pixel circuit is different from a channel width of the first transistor of the second pixel circuit, a channel width of the first transistor of the third pixel circuit is different from a channel width of the first transistor of the fourth pixel circuit, the channel width of the first transistor of the first pixel circuit is equal to the channel width of the first transistor of the third pixel circuit, and the channel width of the first transistor of the second pixel circuit is equal to the channel width of the first transistor of the fourth pixel circuit. The plurality of light-emitting elements includes a first color light-emitting element, a second color light-emitting element, and a third color light-emitting element. The first pixel circuit drives the first color light-emitting element or the third color light-emitting element, the second pixel circuit drives the second color light-emitting element, the third pixel circuit drives the second color light-emitting element, and the fourth pixel circuit drives the third color light-emitting element or the first color light-emitting element.

Other aspects of the present disclosure may be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic diagram of a planar structure of a display panel consistent with the disclosed embodiments of the present disclosure;

FIG. 2 illustrates a schematic diagram of an electrical connection structure of the pixel circuit in FIG. 1, consistent with the disclosed embodiments of the present disclosure;

FIG. 3 illustrates a partially enlarged schematic diagram of a pixel circuit in the J1 region of FIG. 1, consistent with the disclosed embodiments of the present disclosure;

FIG. 4 illustrates a schematic diagram of a layout structure of a pixel circuit and a light-emitting element in existing technology;

FIG. 5 illustrates a schematic curve showing pink or green color deviation caused by differences in corresponding driving current of different pixel circuits in FIG. 4;

FIG. 6 illustrates a partially enlarged schematic diagram of the arrangement of pixel circuits and light-emitting elements in the J1 region of FIG. 1, consistent with the disclosed embodiments of the present disclosure;

FIG. 7 illustrates a schematic diagram of another electrical connection structure of the pixel circuit in FIG. 1, consistent with the disclosed embodiments of the present disclosure;

FIG. 8 illustrates an operation timing diagram of the pixel circuit in FIG. 7, consistent with the disclosed embodiments of the present disclosure;

FIG. 9 illustrates a partially enlarged schematic diagram of the arrangement of light-emitting elements in a partial area of FIG. 1, consistent with the disclosed embodiments of the present disclosure;

FIG. 10 illustrates a schematic diagram of a layout structure combining the pixel circuit of FIG. 3 and the light-emitting element of FIG. 9, consistent with the disclosed embodiments of the present disclosure;

FIG. 11 illustrates a schematic diagram of another layout structure combining the pixel circuit of FIG. 3 and the light-emitting element of FIG. 9, consistent with the disclosed embodiments of the present disclosure;

FIG. 12 illustrates a partially enlarged schematic diagram of the J2 region in FIG. 11, consistent with the disclosed embodiments of the present disclosure;

FIG. 13 illustrates a schematic structural diagram of a cross-section taken along the line A-A′ in FIG. 12, consistent with the disclosed embodiments of the present disclosure;

FIG. 14 illustrates a schematic structural diagram of a cross-section taken along the line B-B′ in FIG. 12, consistent with the disclosed embodiments of the present disclosure;

FIG. 15 illustrates a schematic structural diagram of a cross-section taken along the line C-C′ in FIG. 12, consistent with the disclosed embodiments of the present disclosure;

FIG. 16 illustrates a schematic structural diagram of a cross-section taken along the line D-D′ in FIG. 12, consistent with the disclosed embodiments of the present disclosure;

FIG. 17 illustrates a schematic diagram of another planar structure of a display panel consistent with the disclosed embodiments of the present disclosure;

FIG. 18 illustrates a partially enlarged schematic diagram of the J3 region of FIG. 17, consistent with the disclosed embodiments of the present disclosure;

FIG. 19 illustrates another partially enlarged schematic diagram of the J3 region of FIG. 17, consistent with the disclosed embodiments of the present disclosure;

FIG. 20 illustrates a schematic diagram of another planar structure of a display panel consistent with the disclosed embodiments of the present disclosure;

FIG. 21 illustrates a schematic diagram of another planar structure of a display panel consistent with the disclosed embodiments of the present disclosure;

FIG. 22 illustrates a partially enlarged schematic diagram of the J4 region of FIG. 21, consistent with the disclosed embodiments of the present disclosure;

FIG. 23 illustrates a schematic diagram of a corresponding layout of the pixel circuit and the data line in FIG. 22, consistent with the disclosed embodiments of the present disclosure;

FIG. 24 illustrates a partially enlarged schematic diagram of a corresponding area of the plurality of pixel-circuit column groups in FIG. 21, consistent with the disclosed embodiments of the present disclosure;

FIG. 25 illustrates a schematic diagram of a corresponding layout of the pixel circuit and the data line in FIG. 24, consistent with the disclosed embodiments of the present disclosure; and

FIG. 26 illustrates a schematic diagram of a planar structure of a display device consistent with the disclosed embodiments of the present disclosure.

### DETAILED DESCRIPTION

To make the objectives, technical solutions and advantages of the present disclosure clearer and more explicit, the present disclosure is described in further detail with accompanying drawings and embodiments. It should be understood that the specific exemplary embodiments described herein are only for explaining the present disclosure and are not intended to limit the present disclosure.

It should be noted that in the present disclosure, relational terms such as “first” and “second” are only used to distinguish one entity or operation from another entity or operation, and do not necessarily require or imply that such actual relationship or sequence exists between these entities or operations. Terms “comprise”, “include” or any other variations thereof are intended to cover a non-exclusive inclusion. A process, method, article, or apparatus that includes a series of elements includes not only the series of elements, but also other elements not expressly listed, or elements inherent to such a process, method, article, or apparatus. Without further limitation, an element defined by a statement like “comprises a . . . ” does not exclude the presence of additional identical elements in a process, method, article, or apparatus that includes the foregoing element. In the present disclosure, that layer A and layer B are “disposed on a same layer” means that layer A and layer B are made of a same material and in a same process.

Reference will now be made in detail to embodiments of the present disclosure, which are illustrated in the accompanying drawings. Similar labels and letters designate similar items in the drawings. Once an item is defined in one drawing, the item may not be defined and discussed in subsequent drawings.

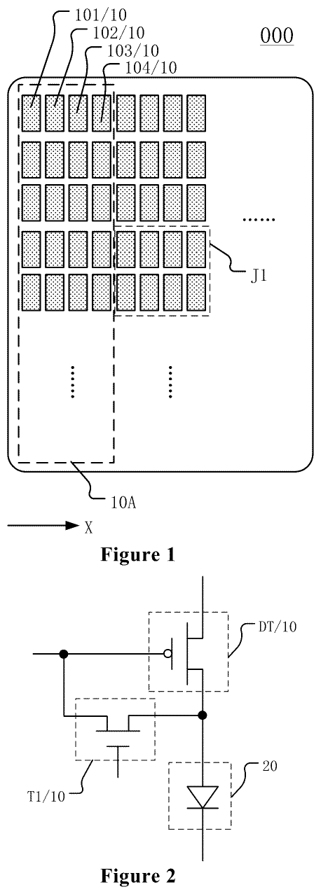

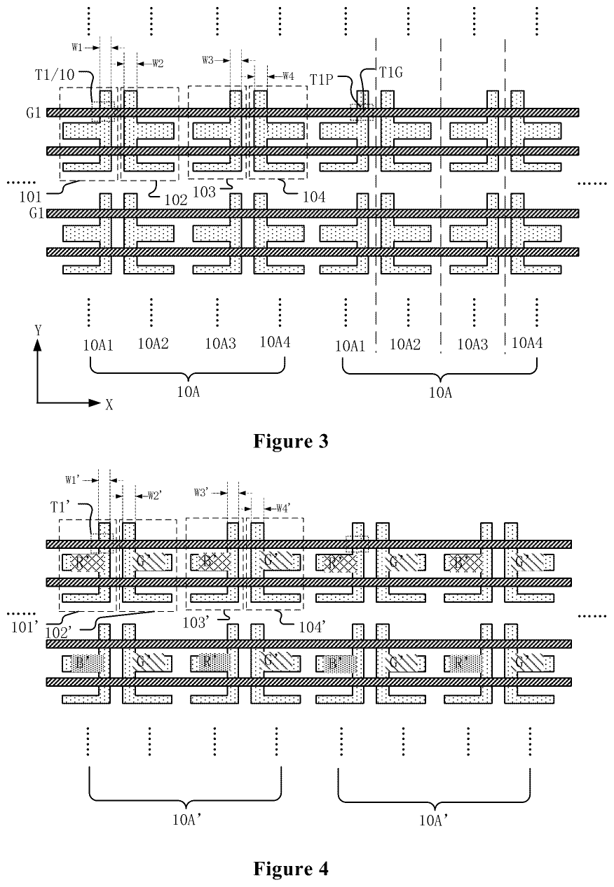

The present disclosure provides a display panel. FIG. 1 illustrates a schematic diagram of a planar structure of a display panel consistent with the disclosed embodiments of the present disclosure, where a block filled with dots represents a pixel circuit. FIG. 2 illustrates a schematic diagram of an electrical connection structure of the pixel circuit in FIG. 1. FIG. 3 illustrates a partially enlarged schematic diagram of a pixel circuit in the J1 region of FIG. 1. Referring to FIGS. 1-3, the display panel 000 includes a plurality of pixel circuits 10. The pixel circuit 10 includes a driving transistor DT and a first transistor T1 that are electrically connected. The plurality of pixel circuits 10 at least includes a first pixel circuit 101, a second pixel circuit 102, a third pixel circuit 103, and a fourth pixel circuit 104.

The display panel 000 includes a plurality of pixel-circuit column groups 10A arranged in sequence along a first direction X. The pixel-circuit column group 10A includes a first pixel-circuit column 10A1, a second pixel-circuit column 10A2, a third pixel-circuit column 10A3, and a fourth pixel-circuit column 10A4. The first pixel-circuit column 10A1 includes a plurality of first pixel circuits 101. The second pixel-circuit column 10A2 includes a plurality of second pixel circuits 102. The third pixel-circuit column 10A3 includes a plurality of third pixel circuits 103. The fourth pixel-circuit column 10A4 includes a plurality of fourth pixel circuits 104.

The channel width W1 of the first transistor T1 of the first pixel circuit 101 is different from the channel width W2 of the first transistor T1 of the second pixel circuit 102. The channel width W3 of the first transistor T1 of the third pixel circuit 103 is different from the channel width W4 of the first transistor T1 of the fourth pixel circuit 104. The channel width W1 of the first transistor T1 of the first pixel circuit 101 is equal to the channel width W3 of the first transistor T1 of the third pixel circuit 103. The channel width W2 of the first transistor T1 of the second pixel circuit 102 is equal to the channel width W4 of the first transistor T1 of the fourth pixel circuit 104.

The display panel 000 includes a plurality of light-emitting elements 20. The plurality of light-emitting elements 20 includes a first color light-emitting element 201, a second color light-emitting element 202, and a third color light-emitting element 203. The first pixel circuit 101 drives the first color light-emitting element 201 or the third color light-emitting element 203. The second pixel circuit 102 drives the second color light-emitting element 202, and the third pixel circuit 103 drives the second color light-emitting element 202. The fourth pixel circuit 104 drives the third color light-emitting element 203 or the first color light-emitting element 201.

Specifically, in one embodiment, the display panel 000 may be an organic light-emitting diode (OLED) display panel. The display panel 000 may include a substrate. The substrate may be used as a carrier substrate for arranging pixel circuits, light-emitting elements and other structures of the display panel 000. The film layer structure of the display panel 000 is not elaborated here. When the display panel 000 is an OLED display panel, the pixel circuits 10 in the display panel 000 may be made of a driving array layer on the substrate. Through a plurality of conductive layers and insulating layers included in the driving array layer, the pixel circuit 10 or the thin film transistor structure, capacitor structure, and driving wiring of other driving circuits may be disposed. The light-emitting element 20 may be disposed on a side of the driving array layer away from the substrate. An anode may be disposed between the light-emitting element and the driving array layer. Details will not be elaborated here, and reference may be made to film layer structures of OLED display panels in the related art.

As shown in FIG. 2, in one embodiment, the pixel circuit 10 at least includes a driving transistor DT and a first transistor T1 electrically connected to the driving transistor DT. The driving transistor DT and the first transistor T1 are configured to generate a driving current and provide the driving current to the light-emitting element 20 electrically connected to the pixel circuit 10, such that the light-emitting element 20 may emit light for display. It may be understood that the first transistor T1 may be any transistor electrically connected to one electrode of the driving transistor DT. For example, in the related art, the pixel circuit 10 includes 7 transistors and 1 capacitor. In this case, the first transistor T1 may be understood as any one of the seven transistors except the driving transistor DT. The first transistor T1 is electrically connected to one electrode (gate, source or drain) of the driving transistor DT.

As shown in FIG. 3, the first direction X may be understood as a direction from one edge of the display panel 000 to another edge opposite thereto. Along the first direction X, the display panel 000 includes a plurality of pixel-circuit column groups 10A arranged in sequence. The pixel-circuit column group 10A includes a first pixel-circuit column 10A1, a second pixel-circuit column 10A2, a third pixel-circuit column 10A3, and a fourth pixel-circuit column 10A4. That is, the pixel-circuit column group 10A includes the first pixel-circuit column 10A1, the second pixel-circuit column 10A2, the third pixel-circuit column 10A3, and the fourth pixel-circuit column 10A4, which are sequentially arranged along the first direction X. The first pixel-circuit column 10A1, the second pixel-circuit column 10A2, the third pixel-circuit column 10A3, and the fourth pixel-circuit column 10A4 may be understood as four adjacent pixel-circuit columns in the first direction X, forming the pixel-circuit column group 10A.

The display panel 000 includes a plurality of pixel circuits 10. The plurality of pixel circuits at least includes a first pixel circuit 101, a second pixel circuit 102, a third pixel circuit 103, and a fourth pixel circuit 104. The first pixel-circuit column 10A1 includes a plurality of first pixel circuits 101. The second pixel-circuit column 10A2 includes a plurality of second pixel circuits 102. The third pixel-circuit column 10A3 includes a plurality of third pixel circuits 103. The fourth pixel-circuit column 10A4 includes the plurality of fourth pixel circuits 104. That is, the plurality of first pixel circuits 101 forms the first pixel-circuit column 10A1. The plurality of second pixel circuits 102 forms the second pixel-circuit column 10A2. The plurality of third pixel circuits 103 forms the third pixel-circuit column 10A3. The plurality of fourth pixel circuits 104 forms the fourth pixel-circuit column 10A4.

During the manufacturing process of the display panel, especially during the manufacturing process of the pixel circuits, errors may be generated due to fluctuations in the manufacturing process. For example, in the pixel-circuit column group 10A including four adjacent pixel-circuit columns in the first direction X, the channel width W1 of the first transistor T1 of the first pixel circuit 101 may be different from the channel width W2 of the first transistor T1 of the second pixel circuit 102. The channel width W3 of the first transistor T1 of the third pixel circuit 103 may be different from the channel width W4 of the first transistor T1 of the fourth pixel circuit 104. The channel width W1 of the first transistor T1 of the first pixel circuit 101 may be equal to the channel width W3 of the first transistor T1 of the third pixel circuit 103. The channel width W2 of the first transistor T1 of the second pixel circuit 102 may be equal to the channel width W4 of the first transistor T1 of the fourth pixel circuit 104.

To clearly illustrate the channel region of the first transistor T1, other film layers of the pixel circuit in FIG. 3 are not illustrated. In a specific implementation, the pixel circuit may also include other conductive film layers, which will not be elaborated here. Referring to FIG. 3, the gate T1G and the semiconductor portion TiP of the first transistor T1 overlap, forming a channel region. The scanning line G1 corresponding to the gate T1G overall extends along the first direction X. The semiconductor portion TiP of the first transistor T1 overall extends along the second direction Y. The first direction X and the second direction Y intersect or are perpendicular to each other. For example, when the first direction X is the horizontal direction in FIG. 3, the second direction Y is the vertical direction in FIG. 3. The channel width of the first transistor T1 is the width of the semiconductor portion TiP of the first transistor T1 in the first direction X. The first direction X is same as the overall extending direction of the scan line G1 corresponding to the gate T1G of the first transistor T1.

It may be understood that the structure of the pixel circuit 10 in FIG. 3 is only an example, for illustrating the channel width of the first transistor T1 in the pixel circuit. During a specific implementation, the circuit layout structure of the pixel circuit 10 may be realized according to the actual electrical connection structure of the pixel circuit. The present disclosure does not limit a specific circuit layout structure.

FIG. 4 illustrates a schematic diagram of a layout structure of a pixel circuit and a light-emitting element in existing technology. In existing technology, under the interference of process fluctuations, in the repeating plurality of pixel-circuit column groups 10A′, the channel width W1′ of the first transistor T1′ of the first pixel circuit 101′ may be different from the channel width W2′ of the first transistor T1′ of the second pixel circuit 102′. The channel width W3′ of the first transistor T1′ of the third pixel circuit 103′ may be different from the channel width W4′ of the first transistor T1′ of the fourth pixel circuit 104′. The driving transistor DT′ is configured to generate a driving current. The difference in channel width of the first transistor T1′ electrically connected to the driving transistor DT′ may cause a difference in coupling capacitance, thereby causing a difference in driving current. For example, the channel width W1′ of the first transistor T1′ of the first pixel circuit 101′ may be small and always correspondingly drive the red light-emitting element R′ or the blue light-emitting element B′. The channel width W2′ of the first transistor T1′ of the second pixel circuit 102′ may be large and always correspondingly drive the green light-emitting element G′. The channel width W3′ of the first transistor T1′ of the third pixel circuit 103′ may be small and always correspondingly drive the red light-emitting element R′ or the blue light-emitting element B′. The channel width W4′ of the first transistor T1′ of the fourth pixel circuit 104′ may be large and always correspondingly drive the green light-emitting element G′. As such, the coupling capacitance in the second pixel circuit 102′ and the fourth pixel circuit 104′, which have a large channel width of the first transistor, may be large, and the driving current generated may be large. That is, the driving current obtained by the green light-emitting element G′ may be large. Accordingly, the brightness of the green light-emitting element G′ may be greater, and the color may be greener. As such, highlighted display may appear greener, resulting in problems of color deviation.

Similarly, for example, the channel width of the first transistor of the first pixel circuit may be large and always correspondingly drive the red light-emitting element or the blue light-emitting element. The channel width of the first transistor of the second pixel circuit may be small and always correspondingly drive the green light-emitting element. The channel width of the first transistor of the third pixel circuit may be large and always correspondingly drive the red light-emitting element or the blue light-emitting element. The channel width of the first transistor of the fourth pixel circuit may be small and always correspondingly drive the green light-emitting element. As such, the coupling capacitance in the first pixel circuit and the third pixel circuit, which have a large channel width of the first transistor, may be large, and the driving current generated may be large. That is, the driving current obtained by the red light-emitting element or the blue light-emitting element may be large, and the color may be pinker. As such, highlighted display may appear pinker, resulting in problems of color deviation.

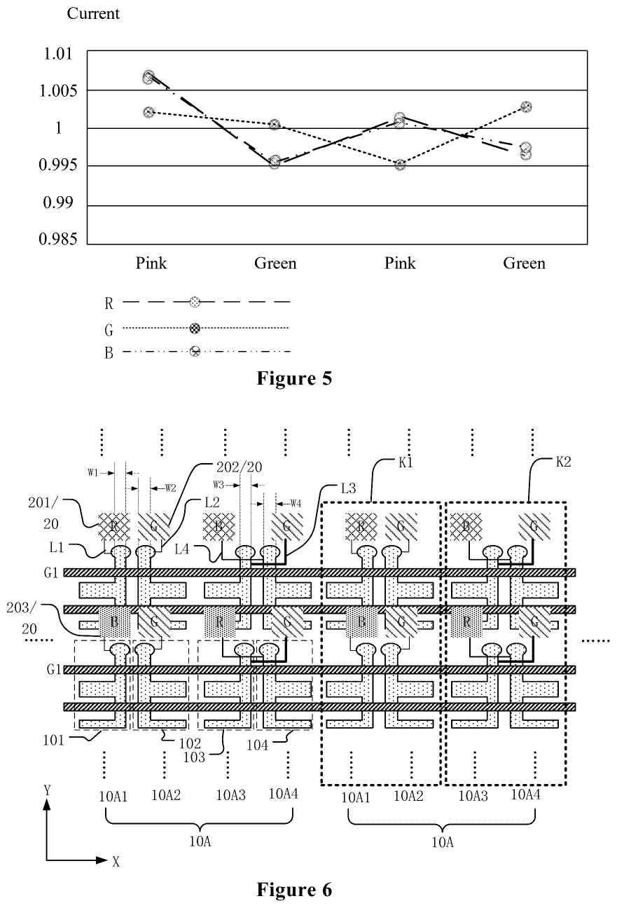

FIG. 5 illustrates a schematic curve showing pink or green color deviation caused by differences in corresponding driving current of different pixel circuits in FIG. 4. Table 1 illustrates the smaller CIEy values and pink color deviation, or the larger CIEy values and green color deviation, caused by the difference in the channel width of the first transistor of different pixel circuits in the display panel of FIG. 4. The CIEy value refers to the Y coordinate value in the color space, which is usually used to represent the brightness or lightness of the color. In the CIE XYZ color space, the Y coordinate represents the brightness component of light, while the X and Z coordinates represent the red and blue color components respectively.

TABLE 1

| | | | Color | Color | | |
|---|---|---|---|---|---|---|
| | ΔCD(G- | Brightness | coordinate | coordinate | | Color |
| Image | RB) | Lv | x | y | Δy | deviation |
| 500 nitL | −0.05 μm | 517.12 | 0.305394 | 0.31315 | −0.00287 | Pink |
| 255 | 0 | 525.25 | 0.304952 | 0.316019 | | |
| | 0.05 μm | 534.11 | 0.304509 | 0.31889 | 0.002871 | Green |
| 500 nitL | −0.05 μm | 112.41 | 0.3050 | 0.3130 | −0.00354 | Pink |
| 127 | 0 | 114.68 | 0.30446 | 0.31654 | | |
| | 0.05 μm | 117.05 | 0.30390 | 0.32018 | 0.00363 | Green |
| 500 nitL | −0.05 μm | 5.52 | 0.305297 | 0.31367 | −0.00431 | Pink |
| 32 | 0 | 5.65 | 0.304633 | 0.317978 | | |
| | 0.05 μm | 5.79 | 0.303988 | 0.322157 | 0.00418 | Green |

Specifically, it may be seen from FIG. 5 and Table 1 that in the repeating plurality of pixel-circuit column groups 10A′ shown in FIG. 4, when the channel width W1′ of the first transistor T1′ of the first pixel circuit 101′ is large and always correspondingly drive the red light-emitting element R′ or the blue light-emitting element B′, the channel width W2′ of the first transistor T1′ of the second pixel circuit 102′ is small and always correspondingly drive the green light-emitting element G′, the channel width W3′ of the first transistor T1′ of the third pixel circuit 103′ is large and always correspondingly drive correspondingly drive the red light-emitting element R′ or the blue light-emitting element B′, and the channel width W4′ of the first transistor T1′ of the fourth pixel circuit 104′ is small and always correspondingly drive the green light-emitting element G′, then the coupling capacitance in the first pixel circuit 101′ and the third pixel circuit 103′ which have a large channel width of the first transistor T1′, may be large, and the driving current generated may be large. That is, the red light-emitting element R′ or the blue light-emitting element B′ may get a larger driving current, the green light-emitting element G′ may get a smaller driving current, and the color may be pinker (such as the driving current value of the pink color deviation shown in FIG. 5). The CIEy value is negative, and a smaller value indicates a pink color deviation (such as the brightness and chromaticity values of the row with pink color deviation in Table 1). That is, the light-emitting element regions driven by the first pixel circuit 101′ and the second pixel circuit 102′ may always have a pink color deviation. The light-emitting element areas corresponding to the third pixel circuit 103′ and the fourth pixel circuit 104′ may also always have a pink color deviation. As such, the display panel may overall have a pink color deviation.

Similarly, in the repeating pixel-circuit column groups 10A′ shown in FIG. 4, when the channel width W1′ of the first transistor T1′ of the first pixel circuit 101′ is small and always correspondingly drive the red light-emitting element R′ or the blue light-emitting element B′, the channel width W2′ of the first transistor T1′ of the second pixel circuit 102′ is large and always correspondingly drive the green light-emitting element G′, the channel width W3′ of the first transistor T1′ of the third pixel circuit 103′ is small and always correspondingly drive the red light-emitting element R′ or the blue light-emitting element B′, and the channel width W4′ of the first transistor T1′ of the fourth pixel circuit 104′ is large and always correspondingly drive the green light-emitting element G′, then, the coupling capacitance in the second pixel circuit 102′ and the fourth pixel circuit 104′, where the channel width of the first transistor T1′ is large, may be large, and the driving current generated may be large. That is, the red light-emitting element R′ or the blue light-emitting element B′ may get smaller driving current, the green light-emitting element G′ may get larger driving current, and the color may be greener (such as the driving current value of the green color deviation shown in FIG. 5). The CIEy value may be positive, and a larger value indicates a green color deviation (such as the brightness and chromaticity values of the row with a green color deviation in Table 1). That is, the light-emitting element regions driven by the first pixel circuit 101′ and the second pixel circuit 102′ may always have a green color deviation. The light-emitting element areas driven by the third pixel circuit 103′ and the fourth pixel circuit 104′ may also always have a green color deviation. As such, the display panel may overall have a green color deviation.

FIG. 6 illustrates a partially enlarged schematic diagram of the arrangement of pixel circuits and light-emitting elements in the J1 region of FIG. 1, consistent with the disclosed embodiments of the present disclosure. Referring to FIGS. 1-3 and 6, in one embodiment, the display panel 000 includes a plurality of light-emitting elements 20. The plurality of light-emitting elements 20 includes a first color light-emitting element 201, a second color light-emitting element 202, and a third color light-emitting element 203 (different colors are distinguished by different filling patterns in FIG. 6). The first pixel circuit 101 drives the first color light-emitting element 201 or the third color light-emitting element 203. The second pixel circuit 102 drives the second color light-emitting element 202. The third pixel circuit 103 drives the second color light-emitting element 202. The fourth pixel circuit 104 drives the third color light-emitting element 203 or the first color light-emitting element 201. That is, the plurality of first pixel circuits 101 forms the first pixel-circuit column 10A1, and the plurality of second pixel circuits 102 forms the second pixel-circuit column 10A2. The channel width W1 of the first transistor T1 of the first pixel circuit 101 may be different from the channel width W2 of the first transistor T1 of the second pixel circuit 102. The first pixel circuit 101 drives the first color light-emitting element 201 or the third color light-emitting element 203. The second pixel circuit 102 drives the second color light-emitting element 202.

The plurality of third pixel circuits 103 forms the third pixel-circuit column 10A3, and the plurality of fourth pixel circuits 104 forms the fourth pixel-circuit column 10A4. The channel width W3 of the first transistor T1 of the third pixel circuit 103 may be different from the channel width W4 of the first transistor T1 of the fourth pixel circuit 104. The channel width W3 of the first transistor T1 of the third pixel circuit 103 may be same as the channel width W1 of the first transistor T1 of the first pixel circuit 101. The channel width W4 of the first transistor T1 of the fourth pixel circuit 104 may be same as the channel width W2 of the first transistor T1 of the second pixel circuit 102. In this case, the color of the light-emitting element driven by the third pixel circuit 103 may be different from the color of the light-emitting element driven by the first pixel circuit 101. The third pixel circuit 103 drives the second color light-emitting element 202. The color of the light-emitting element driven by the fourth pixel circuit 104 may be different from the color of the light-emitting element driven by the second pixel circuit 102. The fourth pixel circuit 104 drives the third color light-emitting element 203 or the first color light-emitting element 201.

As such, when the channel width W1 of the first transistor T1 of the first pixel circuit 101 is greater than the channel width W2 of the first transistor T1 of the second pixel circuit 102, the driving current of the first color light-emitting element 201 or the third color light-emitting element 203 driven by the first pixel circuit 101 may be large, and the driving current of the second color light-emitting element 202 driven by the second pixel circuit 102 may be small. The light-emitting areas corresponding to the first pixel circuit 101 and the second pixel circuit 102 may have a color deviation towards the color of the first color light-emitting element 201 or the third color light-emitting element 203. When the channel width W3 of the first transistor T1 of the third pixel circuit 103 is greater than the channel width W4 of the first transistor T1 of the fourth pixel circuit 104, the driving current of the second color light-emitting element 202 driven by the third pixel circuit 103 may be large, and the driving current of the first color light-emitting element 201 or the third color light-emitting element 203 driven by the fourth pixel circuit 104 may be small. The light-emitting areas corresponding to the third pixel circuit 103 and the fourth pixel circuit 104 may have a color deviation towards the color of the second color light-emitting element 202. Accordingly, in the light-emitting area corresponding to the pixel-circuit column group 10A including four adjacent pixel-circuit columns in the first direction X, the color deviation of the light-emitting areas corresponding to the third pixel circuit 103 and the fourth pixel circuit 104 may be neutralized with the color deviation of the light-emitting areas corresponding to the first pixel circuit 101 and the second pixel circuit 102. As a result, for the overall visual effect, the color deviation problem may be eased, and the display quality may be improved.

Similarly, when the channel width W1 of the first transistor T1 of the first pixel circuit 101 is smaller than the channel width W2 of the first transistor T1 of the second pixel circuit 102, the driving current of the first color light-emitting element 201 or the third color light-emitting element 203 driven by the first pixel circuit 101 may be small, and the driving current of the second color light-emitting element 202 driven by the second pixel circuit 102 may be large. The light-emitting area corresponding to the first pixel circuit 101 and the second pixel circuit 102 may have a color deviation towards the color of the second color light-emitting element 202. When the channel width W3 of the first transistor T1 of the third pixel circuit 103 is smaller than the channel width W4 of the first transistor T1 of the fourth pixel circuit 104, the driving current of the second color light-emitting element 202 driven by the third pixel circuit 103 may be small, and the driving current of the first color light-emitting element 201 or the third color light-emitting element 203 driven by the fourth pixel circuit 104 may be large. The light-emitting area corresponding to the third pixel circuit 103 and the fourth pixel circuit 104 may have a color deviation towards the color of the first color light-emitting element 201 or the third color light-emitting element 203. Accordingly, in the light-emitting area corresponding to a pixel-circuit column group 10A including four adjacent pixel-circuit columns in the first direction X, the color deviation of the light-emitting area corresponding to the third pixel circuit 103 and the fourth pixel circuit 104 may be neutralized with the color deviation of the light-emitting area corresponding to the first pixel circuit 101 and the second pixel circuit 102. As a result, for the overall visual effect, the color deviation and mura problems may be eased, and the display quality may be improved.

The structure for reducing the display color deviation described above has only minor changes to the layout structure of the display panel 000. There is no need to change the layout structure of the pixel circuit and the layout structure of the light-emitting element, nor is there any need to adopt a complex brightness compensation method. It is only necessary that in the pixel-circuit column group 10A including four adjacent pixel-circuit columns in the first direction X, the first pixel circuit 101 drives the first color light-emitting element 201 or the third color light-emitting element 203, the second pixel circuit 102 drives the second color light-emitting element 202, the third pixel circuit 103 drives the second color light-emitting element 202, and the fourth pixel circuit 104 drives the third color light-emitting element 203 or the first color light-emitting element 201. That is, by changing the color of the light-emitting element driven by the third pixel circuit 103 and the color of the light-emitting element driven by the fourth pixel circuit 104, the display color deviation problem may be eased. The structure and fabrication process of the display panel are relatively simple, and process efficiency of the display panel may be improved.

It may be understood that, in one embodiment, the first pixel circuit 101 drives the first color light-emitting element 201 or the third color light-emitting element 203, indicating that the first pixel circuits 101 located in different rows may drive light-emitting elements of different colors. For example, the first pixel circuit 101 in the first row may drive the first color light-emitting element 201, and the first pixel circuit 101 in the second row may drive the third color light-emitting element 203. The fourth pixel circuit 104 may drive the third color light-emitting element 203 or the first color light-emitting element 201, indicating that the fourth pixel circuits 104 located in different rows may drive light-emitting elements of different colors. For example, the fourth pixel circuit 104 in the first row may drive the third color light-emitting element 203, and the fourth pixel circuit 104 in the second row may drive the first color light-emitting element 201. The first pixel circuit 101 and the fourth pixel circuit 104 in a same row may drive light-emitting elements of different colors. When the first pixel circuit 101 in the first row drives the first color light-emitting element 201, the fourth pixel circuit 104 in the first row may drive the third color light-emitting element 203. When the first pixel circuit 101 in the second row drives the third color light-emitting element 203, the fourth pixel circuit 104 in the second row may drive the first color light-emitting element 201.

It may be understood that the arrangement of the plurality of light-emitting elements 20 included in the display panel 000 may adopt the arrangement method in existing technology. FIG. 6 only shows an example, and other arrangements may be adopted in specific implementations.

Optionally, in one embodiment, the first pixel circuit 101 drives the first color light-emitting element 201 or the third color light-emitting element 203. The second pixel circuit 102 drives the second color light-emitting element 202, and the third pixel circuit 103 drives the second color light-emitting element 202. The fourth pixel circuit 104 drives the third color light-emitting element 203 or the first color light-emitting element 201. Driving may be realized through connection lines. As shown in FIG. 6, the first pixel circuit 101 is electrically connected to and drives the first color light-emitting element 201 or the third color light-emitting element 203 through the connection line L1. The second pixel circuit 102 is electrically connected to and drives the second color light-emitting element 202 through the connection line L2. The third pixel circuit 103 is electrically connected to and drives the second color light-emitting element 202 through the connection line L3. The fourth pixel circuit 104 is electrically connected to and drives the third color light-emitting element 203 or the first color light-emitting element 201 through the connection line L4. As such, the color of the light-emitting element driven by the third pixel circuit 103 is different from the color of the light-emitting element driven by the first pixel circuit 101. The color of the light-emitting element driven by the third pixel circuit 103 is same as the color of the light-emitting element driven by the second pixel circuit 102. The color of the light-emitting element driven by the fourth pixel circuit 104 is different from the color of the light-emitting element driven by the second pixel circuit 102. The color of the light-emitting element driven by the fourth pixel circuit 104 is same as the color of the light-emitting element driven by the first pixel circuit 101.

As a result, in the light-emitting area corresponding to a pixel-circuit column group 10A including four adjacent pixel-circuit columns in the first direction X, the color deviation of the light-emitting areas corresponding to the third pixel circuit 103 and the fourth pixel circuit 104 may be neutralized with the color deviation of the light-emitting area corresponding to the first pixel circuit 101 and the second pixel circuit 102. Accordingly, from the overall visual effect, the color deviation problem may be eased, and the display quality may be improved.

It should be noted that FIGS. 1-3 and 6 only show exemplary structures of the display panel 000. In a specific implementation, the structure of the display panel may include but is not limited to the configurations shown in FIGS. 1-3 and 6. The present disclosure does not limit a specific structure of the display panel, including the shape, quantity and area of the display panel. The shape of the light-emitting element 20 shown in FIG. 6 is only an example, and the shape and arrangement of the pixel circuit 10 are also only an example. The structure of the display panel may be designed according to actual needs during specific implementation.

Optionally, as shown in FIG. 6, the first color light-emitting element 201 is one of a red light-emitting element or a blue light-emitting element. The third color light-emitting element 203 is the other of the red light-emitting element or the blue light-emitting element. The second color light-emitting element 202 is a green light-emitting element. For example, the first color light-emitting element 201 is a red light-emitting element, the second color light-emitting element 202 is a green light-emitting element, and the third color light-emitting element 203 is a blue light-emitting element.

When the channel width W1 of the first transistor T1 of the first pixel circuit 101 is greater than the channel width W2 of the first transistor T1 of the second pixel circuit 102, the driving current of the first color light-emitting element 201 or the third color light-emitting element 203 driven by the first pixel circuit 101 may be large. The driving current of the second pixel circuit 102 driving the second color light-emitting element 202 may be small. The light-emitting area (K1 area as shown in FIG. 6) corresponding to the first pixel circuit 101 and the second pixel circuit 102 may be biased towards the color of the first color light-emitting element 201 or the third color light-emitting element 203, that is, biased towards pink.

When the channel width W3 of the first transistor T1 of the third pixel circuit 103 is greater than the channel width W4 of the first transistor T1 of the fourth pixel circuit 104, the driving current of the second color light-emitting element 202 driven by the third pixel circuit 103 may be large. The driving current of the first color light-emitting element 201 or the third color light-emitting element 203 driven by the fourth pixel circuit 104 may be small. The light-emitting area (K2 area as shown in FIG. 6) corresponding to the third pixel circuit 103 and the fourth pixel circuit 104 may be biased towards the color of the second color light-emitting element 202, that is, biased towards green.

As such, in the light-emitting area corresponding to a pixel-circuit column group 10A including four adjacent pixel-circuit columns in the first direction X, the color deviation toward green, of the light-emitting areas corresponding to the third pixel circuit 103 and the fourth pixel circuit 104 may be neutralized by the color deviation toward pink, of the light-emitting areas corresponding to the first pixel circuit 101 and the second pixel circuit 102. Accordingly, from the overall visual effect, the color deviation problem may be eased, and the display quality may be improved.

Similarly, when the channel width W1 of the first transistor T1 of the first pixel circuit 101 is smaller than the channel width W2 of the first transistor T1 of the second pixel circuit 102, the driving current of the first color light-emitting element 201 or the third color light-emitting element 203 driven by the first pixel circuit 101 may be small. The driving current of the second color light-emitting element 202 driven by the second pixel circuit 102 drives may be large. The light-emitting areas corresponding to the first pixel circuit 101 and the second pixel circuit 102 may be biased towards the color of the second color light-emitting element 202, that is, biased towards green.

When the channel width W3 of the first transistor T1 of the third pixel circuit 103 is smaller than the channel width W4 of the first transistor T1 of the fourth pixel circuit 104, the driving current of the second color light-emitting element 202 driven by the third pixel circuit 103 may be small, and the driving current of the first color light-emitting element 201 or the third color light-emitting element 203 driven by the fourth pixel circuit 104 may be large. The light-emitting areas corresponding to the third pixel circuit 103 and the fourth pixel circuit 104 may be biased towards the color of the first color light-emitting element 201 or the third color light-emitting element 203, that is, biased towards pink.

As such, in the light-emitting area corresponding to the pixel-circuit column group 10A including four adjacent pixel-circuit columns in the first direction X, the color deviation toward pink, of the light-emitting area corresponding to the third pixel circuit 103 and the fourth pixel circuit 104 may be neutralized by the color deviation toward green, of the light-emitting area corresponding to the first pixel circuit 101 and the second pixel circuit 102. Accordingly, for the overall visual effect, the color deviation problem may be eased, and the display quality may be improved.

Optionally, as shown in FIG. 3 and FIG. 6, in one embodiment, during the manufacturing process of the display panel 000, especially during the manufacturing process of the pixel circuits 10, due to process fluctuations, manufacturing errors may be generated. As a result, in the pixel-circuit column group 10A including four adjacent pixel-circuit columns in the first direction X, the channel width W1 of the first transistor T1 of the first pixel circuit 101 may be different from the channel width W2 of the first transistor T1 of the second pixel circuit 102. The channel width W3 of the first transistor T1 of the third pixel circuit 103 may be different from the channel width W4 of the first transistor T1 of the fourth pixel circuit 104. The channel width W1 of the first transistor T1 of the first pixel circuit 101 may be equal to the channel width W3 of the first transistor T1 of the third pixel circuit 103. The channel width W2 of the first transistor T1 of the second pixel circuit 102 may be equal to the channel width W4 of the first transistor T1 of the fourth pixel circuit 104.

The above difference caused by process fluctuations may be minimized by adjusting the manufacturing process. For example, the difference between the channel width W1 of the first transistor T1 of the first pixel circuit 101 and the channel width W2 of the first transistor T1 of the second pixel circuit 102 may be controlled within an approximate range of |W1-W2|≤0.1 μm. The difference between the channel width W3 of the first transistor T1 of the third pixel circuit 103 and the channel width W4 of the first transistor T1 of the fourth pixel circuit 104 may be controlled within an approximate range of |W3-W4|≤0.1 μm. As such, within the adjustable range of the process, the difference between the driving currents of different pixel circuits 10 caused by process fluctuations may be minimized. Accordingly, the problem of color deviation may be eased, and the visual effects and enhance display effects may be improved.

The present disclosure takes an example for explanation that the channel width W1 of the first transistor T1 of the first pixel circuit 101 is smaller than the channel width W2 of the first transistor T1 of the second pixel circuit 102, the channel width W3 of the first transistor T1 of the third pixel circuit 103 is smaller than the channel width W4 of the first transistor T1 of the fourth pixel circuit 104. In a specific implementation, the channel width W1 of the first transistor T1 of the first pixel circuit 101 may be greater than the channel width W2 of the first transistor T1 of the second pixel circuit 102, and the channel width W3 of the first transistor T1 of the third pixel circuit 103 may be greater than the channel width W4 of the first transistor T1 of the fourth pixel circuit 104. The present does not limit a specific relationship among the channel widths W1, W2, W3 and W4.

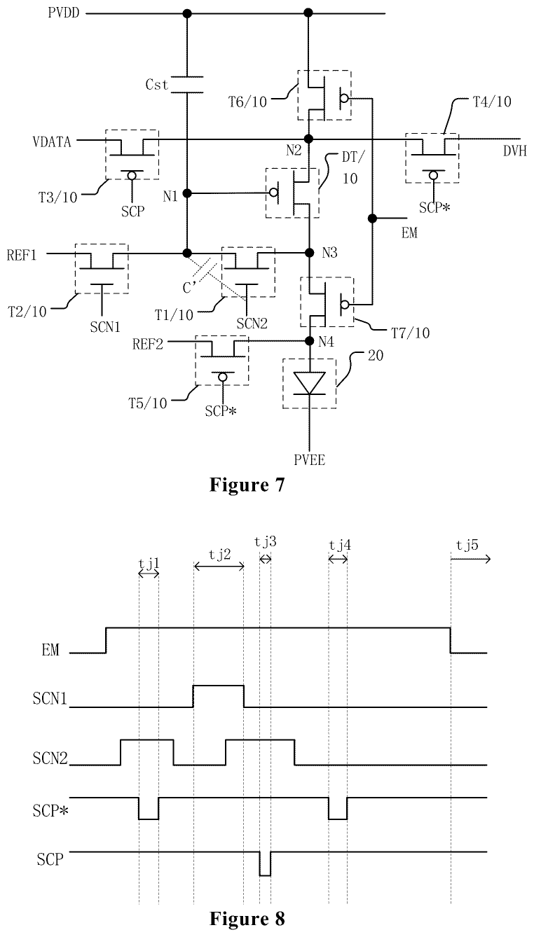

FIG. 7 illustrates a schematic diagram of another electrical connection structure of the pixel circuit in FIG. 1, consistent with the disclosed embodiments of the present disclosure. Referring to FIGS. 1, 3, 6 and 7, in one embodiment, the first transistor T1 is electrically connected between the gate and the first electrode of the driving transistor DT, and the first transistor T1 is an N-type transistor. Optionally, the first transistor T1 may be an N-type metal oxide transistor, and other transistors in the pixel circuit 10 may be P-type low-temperature polysilicon transistors. As shown in FIG. 7, in one embodiment, as an example, the pixel circuit 10 may include 8 transistors and 1 storage capacitor Cst. As shown in FIG. 7, the first transistor T1 may be a transistor that plays a role of threshold compensation and may be electrically connected between the gate (first node N1) and the first electrode (third node N3) of the driving transistor DT. In some other embodiments, the first transistor T1 may be a transistor electrically connected between the gate (first node N1) of the driving transistor DT and the first reference voltage signal terminal REF1 in FIG. 7, and play a role in resetting the gate of the driving transistor DT.

It should be noted that, in one embodiment, the first transistor T1 is electrically connected between the gate and the first electrode of the driving transistor DT. The first electrode of the driving transistor DT may be one of the drain and the source, and the second electrode of the driving transistor DT may be the other of the drain and the source. As an example for illustration, FIG. 7 takes the first electrode as the drain.

In one embodiment, the pixel circuit 10 shown in FIG. 7 is taken as an example. In different pixel circuits 10, the channel width of the first transistor T1 electrically connected between the gate (first node N1) and the first electrode (third node N3) of the driving transistor DT and playing a threshold compensation role may have slight differences due to process fluctuations. For example, the channel width W1 of the first transistor T1 of the first pixel circuit 10 may be smaller than the channel width W2 of the first transistor T1 of the second pixel circuit 102. The channel width W3 of the first transistor T1 of the third pixel circuit 103 may be smaller than the channel width W4 of the first transistor T1 of the fourth pixel circuit 104. The channel width W1 of the first transistor T1 of the first pixel circuit 10 may be equal to the channel width W3 of the first transistor T1 of the third pixel circuit 103. The channel width W2 of the first transistor T1 of the second pixel circuit 102 may be equal to the channel width W4 of the first transistor T1 of the fourth pixel circuit 104.

As such, in the light-emitting stage of the driving process of the display panel, the first transistor T1 may be turned off Since the first transistor T1 is an N-type transistor, the gate of the first transistor T1 is at a low potential. The potentials of the first node N1 and the third node N3 may be pulled down due to the coupling of the gate potential of the first transistor T1 (there is a coupling capacitor C′ between the first node N1 and the gate of the first transistor T1, and the coupling relationship is represented by dotted lines in FIG. 7). The parasitic capacitance of the third node N3 may be very small, that is, the potential of the third node N3 may be pulled very low. Since the charge balance between the first node N1 and the third node N3 is maintained during the pull-down process, the potential of the first node N1 may also be pulled very low along with the third node N3.

When the channel width W2 of the first transistor T1 of the second pixel circuit 102 is larger, compared with the potential of the first node N1 of the first pixel circuit 101, the potential of the first node N1 of the second pixel circuit 102 may be pulled lower. As such, the driving current on the driving transistor DT of the second pixel circuit 102 may be larger, and the light brightness may be brighter. That is, the second color light-emitting element 202 driven by the second pixel circuit 102 may be brighter, and the light-emitting area driven by the second pixel circuit 102 may be more biased toward the color of the second color light-emitting element 202, such as green.

In some other embodiments, when the first transistor T1 is a transistor electrically connected between the gate (first node N1) of the driving transistor DT and the first reference voltage signal terminal REF1 in FIG. 7 and plays a role in resetting the gate of the driving transistor DT, the principle of the color deviation problem caused by the driving current difference may be same as above, and will not be elaborated here.

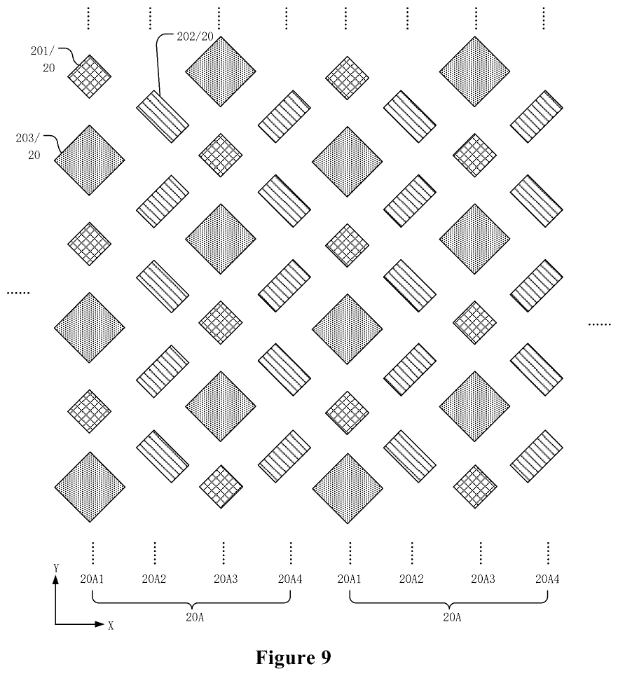

FIG. 8 illustrates an operation timing diagram of the pixel circuit in FIG. 7, consistent with the disclosed embodiments of the present disclosure. In one embodiment, taking the pixel circuit 10 shown in FIG. 7 as an example, referring to FIG. 8, when performing a driving operation, the display panel 000 may include a first bias adjustment stage tj 1, a reset stage tj2, a threshold compensation and data writing stage tj3, a second bias adjustment stage tj4, and a light-emitting stage tj5.

In the first bias adjustment stage tj 1, that is, before resetting the gate of the driving transistor DT, the bias control signal terminal SCP* inputs a low-level bias control signal to control the fourth transistor T4 to be turned on, and the second scan signal terminal SCN2 inputs a high-level second scan signal to control the first transistor T1 to be turned on. As such, the bias adjustment signal provided by the bias adjustment signal terminal DVH may be transmitted to the gate of the driving transistor DT (i.e., the first node N1) through the fourth transistor T4 and the first transistor T1. The bias state of the driving transistor DT may be adjusted for a first time, such that the driving transistor DT may be reverse biased, and the source and drain of the driving transistor DT may be reversed. The degree of ion polarization inside the driving transistor DT may be weakened, and the threshold voltage of the driving transistor DT may be reduced. As such, the threshold voltage of the driving transistor DT may be adjusted by biasing the driving transistor DT, and the threshold voltage drift problem caused by the hysteresis effect of the driving transistor DT due to the forward bias state of the driving transistor DT, may be compensated.

In addition, the low-level bias control signal input by the bias control signal terminal SCP* may also control the fifth transistor T5 to be turned on. The second reference voltage signal terminal REF2 may reset the anode of the light-emitting element 20 (i.e., the fourth node N4) through the fifth transistor T5. As such, the anode of the light-emitting element 20 may be initialized, thereby reducing the residual of the data signal of a previous frame, improving the afterimage phenomenon, and enhancing the display effect of the display panel 000.

In the reset stage tj2, the first scanning signal terminal SCN1 inputs a high-level first scanning signal to control the second transistor T2 to be turned on. The second reference voltage signal terminal REF2 may reset the gate of the driving transistor DT (i.e., the first node N1), and refresh the gate potential of the driving transistor DT in the previous frame.

In the threshold compensation and data writing stage tj3, the third scanning signal terminal SCP inputs a low-level third scanning signal to control the third transistor T3 to be turned on. The second scanning signal terminal SCN2 inputs a high-level second scanning signal to control the first transistor T1 to be turned on. The data line of the display panel provides a data voltage VDATA. The data voltage VDATA may be transmitted to the gate of the driving transistor DT through the third transistor T3, the driving transistor DT and the first transistor T1. The data voltage VDATA may provide threshold compensation on the driving transistor DT, and the deviation of the threshold voltage of the driving transistor DT may be compensated.

In the second bias adjustment stage tj4, the bias control signal terminal SCP* inputs a low-level bias control signal to control the fourth transistor T4 to be turned on. The bias adjustment signal provided by the bias adjustment signal terminal DVH may be transmitted to the source electrode (i.e., the second node N2) of the driving transistor DT through the fourth transistor T4, to adjust the bias state of the driving transistor DT for a second time.

In the light-emitting stage tj5, the light-emitting control signal terminal EM inputs a low-level light-emitting control signal to control the sixth transistor T6 and the seventh transistor T7 to be turned on. The driving transistor DT may generate a driving current under the control of the gate voltage of the driving transistor DT. A conductive path may be formed among the first power signal terminal PVDD, the sixth transistor T6, the driving transistor DT, the seventh transistor T7, the light-emitting element 20, and the second power signal terminal PVEE. A driving current may be provided to the light-emitting element 20 to control the light-emitting element 20 to emit light.

Optionally, in one embodiment, in the pixel circuit 10, the transistor that is electrically connected to the anode of the light-emitting element 20 and drives the light-emitting element 20 to emit light is the seventh transistor T7. The fifth transistor T5 is also electrically connected to the anode of the light-emitting element 20 for resetting the light-emitting element 20.

It may be understood that the electrical connection structure of the pixel circuit 10 provided in FIG. 7 is only an example. During a specific implementation, the electrical connection structure of the pixel circuit 10 includes but is not limited to the electrical connection structure shown in FIG. 7, and may also be other circuit structures.

Still referring to FIGS. 1, 3 and 6, in one embodiment, in the first direction X, the first pixel circuit 101 of the first pixel-circuit column 10A1 and the second pixel circuit 102 of the second pixel-circuit column 10A2 are mirror-symmetrical. The third pixel circuit 103 of the third pixel-circuit column 10A3 and the fourth pixel circuit 104 of the fourth pixel-circuit column 10A4 are mirror-symmetrical.

In one embodiment, the layout structure of the pixel circuit 10 of the display panel 000 may be a structure in which two adjacent pixel circuits 10 are mirror-symmetrical. For example, in the first direction X, the first pixel circuit 101 of the first pixel-circuit column 10A1 and the second pixel circuit 102 of the second pixel-circuit column 10A2 are mirror-symmetrical. The third pixel circuit 103 of the third pixel-circuit column 10A3 and the fourth pixel circuit 104 of the fourth pixel-circuit column 10A4 are mirror-symmetric. In this way, the layout space of the panel may be saved.

It is understandable that the mirror symmetry here is not strictly identical. It may be understood that in the first direction X, the first pixel circuit 101 of the first pixel-circuit column 10A1 and the second pixel circuit 102 of the second pixel-circuit column 10A2 are approximately mirror-symmetric. The third pixel circuit 103 of the third pixel-circuit column 10A3 and the fourth pixel circuit 104 of the fourth pixel-circuit column 10A4 are approximately mirror-symmetrical. That is, in practical production, due to process fluctuations, the size, width and other structures of each film layer structure may not be strictly symmetrical. However, in the first direction X, the corresponding transistor structures and capacitor structures in the first pixel circuit 101 of the first pixel-circuit column 10A1 and the corresponding transistor structures and capacitor structures in the second pixel circuit 102 of the second pixel-circuit column 10A2 are symmetrical to each other. For example, in practical manufacturing, the width of the semiconductor layer of the semiconductor part of the thin film transistor used to make the pixel circuit may vary due to process fluctuations. As such, the color deviation problem caused by the difference in driving currents of different pixel circuits, to be solved by the present disclosure, may occur.

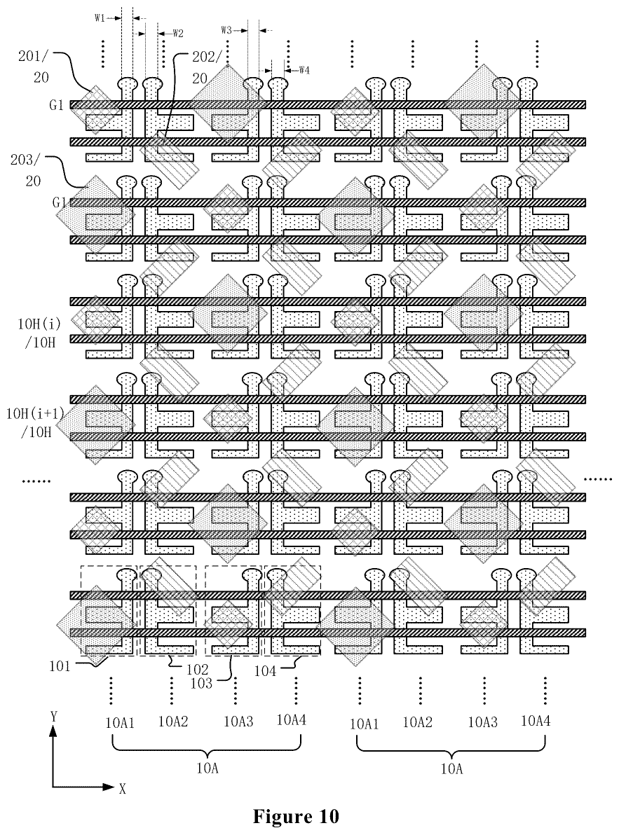

FIG. 9 illustrates a partially enlarged schematic diagram of the arrangement of light-emitting elements in a partial area of FIG. 1. FIG. 10 illustrates a schematic diagram of a layout structure combining the pixel circuit of FIG. 3 and the light-emitting element of FIG. 9. To clearly illustrate the structure, the light-emitting element in FIG. 10 is filled with different transparency degrees. In some embodiments, referring to FIGS. 1, 3, 9 and 10, the display panel 000 includes a plurality of light-emitting element column groups 20A sequentially arranged along the first direction X. One light-emitting element column group 20A includes a first light-emitting element column 20A1, a second light-emitting element column 20A2, a third light-emitting element column 20A3 and a fourth light-emitting element column 20A4 sequentially arranged along the first direction X.

Along the second direction Y, the first light-emitting element column 20A1 includes a plurality of first color light-emitting elements 201 and third color light-emitting elements 203 that are alternately arranged. The second light-emitting element column 20A2 includes a plurality of second color light-emitting elements 202. The third light-emitting element column 20A3 includes a plurality of third color light-emitting elements 203 and first color light-emitting elements 201 that are alternately arranged. The fourth light-emitting element column 20A4 includes a plurality of second color light-emitting elements 202. The first direction X and the second direction Y intersect on a plane parallel to the display panel 000. In one embodiment, as an example, the first direction X and the second direction Y are perpendicular to each other on a plane parallel to the display panel 000.

A plurality of pixel circuits 10 are arranged along a first direction X to form a pixel circuit row 10H. Along the second direction Y, in an i-th pixel circuit row 10H(i) (where i is a positive integer), the first pixel circuit 101 is electrically connected to the first color light-emitting element 201 of the first light-emitting element column 20A1. The second pixel circuit 102 is electrically connected to the second color light-emitting element 202 of the second light-emitting element column 20A2. The third pixel circuit 103 is electrically connected to the second color light-emitting element 202 of the fourth light-emitting element column 20A4. The fourth pixel circuit 104 is electrically connected to the third color light-emitting element 203 of the third light-emitting element column 20A3.

Optionally, along the second direction Y, in an (i+1)-th pixel circuit row 10H(i+1), the first pixel circuit 101 is electrically connected to the third color light-emitting element 203 of the first light-emitting element column 20A1. The second pixel circuit 102 is electrically connected to the second color light-emitting element 202 of the second light-emitting element column 20A2. The third pixel circuit 103 is electrically connected to the second color light-emitting element 202 of the fourth light-emitting element column 20A4. The fourth pixel circuit 104 is electrically connected to the first color light-emitting element 201 of the third light-emitting element column 20A3.

In one embodiment, the display panel 000 includes a plurality of light-emitting elements 20. The plurality of light-emitting elements 20 includes a first color light-emitting element 201, a second color light-emitting element 202, and a third color light-emitting element 203 (in FIG. 9, different colors are indicated by different filling patterns). The arrangement structure of the plurality of light-emitting elements 20 may be a first light-emitting element column 20A1, a second light-emitting element column 20A2, a third light-emitting element column 20A3 and a fourth light-emitting element column 20A4 sequentially arranged along the first direction X to form a light-emitting element column group 20A. The light-emitting element column group 20A is driven by the pixel-circuit column group 10A to emit light. Along the second direction Y, the first light-emitting element column 20A1 includes a plurality of first color light-emitting elements 201 and third color light-emitting elements 203 that are alternately arranged. The second light-emitting element column 20A2 includes a plurality of second color light-emitting elements 202. The third light-emitting element column 20A3 includes a plurality of third color light-emitting elements 203 and first color light-emitting elements 201 that are alternately arranged. The fourth light-emitting element column 20A4 includes a plurality of second color light-emitting elements 202. That is, the arrangement method of the light-emitting elements 20 is a common arrangement method in existing technology.

The first color light-emitting element 201 and the third color light-emitting element 203 may be a red light-emitting element and a blue light-emitting element, respectively. The second color light-emitting element 202 may be a green light-emitting element. As such, when the pixel circuit and the driving structure of the light-emitting element shown in FIG. 4 in existing technology are adopted, when the pixel circuit has process fluctuations that cause differences in driving current, the first light-emitting element column 20A1 and the second light-emitting element column 20A2 may be biased to pink overall, and the third light-emitting element column 20A3 and the fourth light-emitting element column 20A4 may also be biased to pink overall. As such, the overall visual effect of the display panel may have color deviation and mura visual effect problems caused by color deviation to pink. Alternatively, when the pixel circuit and the driving structure of the light-emitting element shown in FIG. 4 in existing technology are adopted, when the pixel circuit has process fluctuations that cause differences in driving current, the first light-emitting element column 20A1 and the second light-emitting element column 20A2 may be biased to green overall. The third light-emitting element column 20A3 and the fourth light-emitting element column 20A4 may also be biased to green overall. As such, the overall visual effect of the display panel may have color deviation and mura visual effect problems caused by color deviation to green.

In one embodiment, when the pixel circuit 10 and the light-emitting element 20 are disposed in combination, the arrangement structures of the pixel circuit 10 and the light-emitting element 20 may not be changed. Along the second direction Y, in the i-th pixel circuit row 10H(i), the first pixel circuit 101 is electrically connected to the first color light-emitting element 201 of the first light-emitting element column 20A1, such that the first pixel circuit 101 drives the first color light-emitting element 201. The second pixel circuit 102 is electrically connected to the second color light-emitting element 202 of the second light-emitting element column 20A2, such that the second pixel circuit 102 drives the second color light-emitting element 202. The third pixel circuit 103 is electrically connected to the second color light-emitting element 202 of the fourth light-emitting element column 20A4, such that the third pixel circuit 103 also drives the second color light-emitting element 202. The fourth pixel circuit 104 is electrically connected to the third color light-emitting element 203 of the third light-emitting element column 20A3, such that the fourth pixel circuit 104 drives the third color light-emitting element 203.

In addition, in the (i+1)-th pixel circuit row 10H(i+1) adjacent to the i-th pixel circuit row 10H(i), the first pixel circuit 101 is electrically connected to the third color light-emitting element 203 of the first light-emitting element column 20A1, such that the first pixel circuit 101 drives the third color light-emitting element 203. The second pixel circuit 102 is electrically connected to the second color light-emitting element 202 of the second light-emitting element column 20A2, such that the second pixel circuit 102 drives the second color light-emitting element 202. The third pixel circuit 103 is electrically connected to the second color light-emitting element 202 of the fourth light-emitting element column 20A4, such that the third pixel circuit 103 drives the second color light-emitting element 202. The fourth pixel circuit 104 is electrically connected to the first color light-emitting element 201 of the third light-emitting element column 20A3, such that the fourth pixel circuit 104 drives the first color light-emitting element 201.

That is, the plurality of first pixel circuits 101 forms the first pixel-circuit column 10A1, and the plurality of second pixel circuits 102 forms the second pixel-circuit column 10A2. The channel width W1 of the first transistor T1 of the first pixel circuit 101 may be different from the channel width W2 of the first transistor T1 of the second pixel circuit 102. The first pixel circuit 101 drives the first color light-emitting element 201 or the third color light-emitting element 203. The second pixel circuit 102 drives the second color light-emitting element 202. The plurality of third pixel circuits 103 forms the third pixel-circuit column 10A3, and the plurality of fourth pixel circuits 104 forms the fourth pixel-circuit column 10A4. The channel width W3 of the first transistor T1 of the third pixel circuit 103 may be different from the channel width W4 of the first transistor T1 of the fourth pixel circuit 104. The channel width W3 of the first transistor T1 of the third pixel circuit 103 may be same as the channel width W1 of the first transistor T1 of the first pixel circuit 101. The channel width W4 of the first transistor T1 of the fourth pixel circuit 104 may be same as the channel width W2 of the first transistor T1 of the second pixel circuit 102. In this case, the color of the light-emitting element driven by the third pixel circuit 103 may be different from the color of the light-emitting element driven by the first pixel circuit 101. The color of the light-emitting element driven by the third pixel circuit 103 may be same as the color of the light-emitting element driven by the second pixel circuit 102. The third pixel circuit 103 drives the second color light-emitting element 202. The color of the light-emitting element driven by the fourth pixel circuit 104 may be different from the color of the light-emitting element driven by the second pixel circuit 102. The color of the light-emitting element driven by the fourth pixel circuit 104 may be same as the color of the light-emitting element driven by the first pixel circuit 101. The color of the light-emitting element driven by the fourth pixel circuit 104 may be same as the color of the light-emitting element driven by the first pixel circuit 101. The fourth pixel circuit 104 drives the third color light-emitting element 203 or the first color light-emitting element 201.

When the channel width W1 of the first transistor T1 of the first pixel circuit 101 is smaller than the channel width W2 of the first transistor T1 of the second pixel circuit 102, the driving current of the first color light-emitting element 201 or the third color light-emitting element 203 driven by the first pixel circuit 101 may be small, and the driving current of the second color light-emitting element 202 driven by the second pixel circuit 102 may be large. The light-emitting areas corresponding to the first pixel circuit 101 and the second pixel circuit 102 may be biased towards the color of the second color light-emitting element 202, that is, biased towards green.

When the channel width W3 of the first transistor T1 of the third pixel circuit 103 is smaller than the channel width W4 of the first transistor T1 of the fourth pixel circuit 104, the driving current of the second color light-emitting element 202 driven by the third pixel circuit 103 may be small, and the driving current of the first color light-emitting element 201 or the third color light-emitting element 203 driven by the fourth pixel circuit 104 may be large. The light-emitting areas corresponding to the third pixel circuit 103 and the fourth pixel circuit 104 may be biased towards the color of the first color light-emitting element 201 or the third color light-emitting element 203, that is, biased towards pink.

As such, in the light-emitting area corresponding to a pixel-circuit column group 10A including four adjacent pixel-circuit columns in the first direction X, the color deviation to pink, of the light-emitting area corresponding to the third pixel circuit 103 and the fourth pixel circuit 104 may be neutralized by the color deviation to green, of the light-emitting area corresponding to the first pixel circuit 101 and the second pixel circuit 102. Accordingly, for the overall visual effect, the color deviation problem may be eased, and the display quality may be improved.

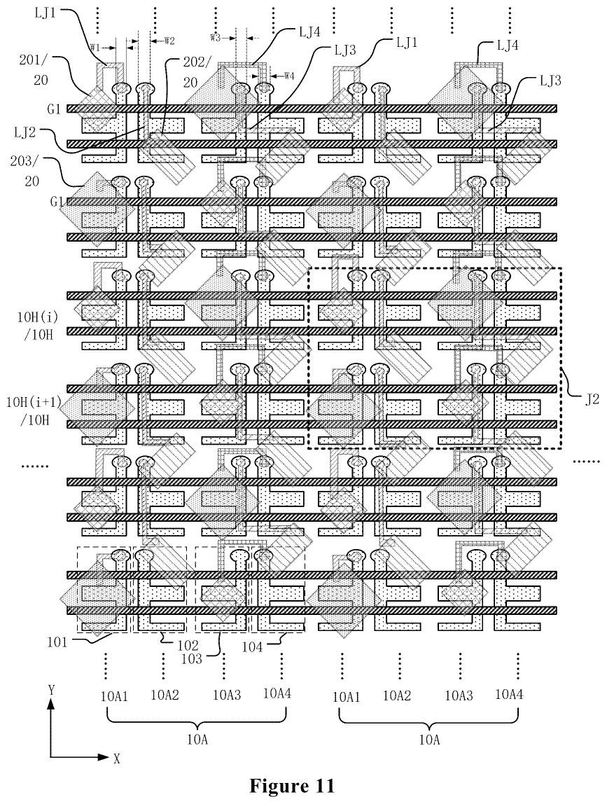

FIG. 11 illustrates a schematic diagram of another layout structure combining the pixel circuit of FIG. 3 and the light-emitting element of FIG. 9. To clearly illustrate the structure, the light-emitting elements and the connection lines in FIG. 11 are filled with different transparency degrees. Referring to FIGS. 1, 3, and 9-11, in one embodiment, the first pixel circuit 101 is electrically connected to the first color light-emitting element 201 of the first light-emitting element column 20A1 through the first connection line LJ1. The second pixel circuit 102 is electrically connected to the second color light-emitting element 202 of the second light-emitting element column 20A2 through the second connection line LJ2. The third pixel circuit 103 is electrically connected to the second color light-emitting element 202 of the fourth light-emitting element column 20A4 through the third connection line LJ3. The fourth pixel circuit 104 is electrically connected to the third color light-emitting element 203 of the third light-emitting element column 20A3 through the fourth connection line LJ4.

In one embodiment, a light-emitting element column group 20A includes a first light-emitting element column 20A1, a second light-emitting element column 20A2, a third light-emitting element column 20A3 and a fourth light-emitting element column 20A4 sequentially arranged along the first direction X. The light-emitting element column group 20A is driven by a pixel-circuit column group 10A to emit light. The pixel-circuit column group 10A includes a first pixel-circuit column 10A1, a second pixel-circuit column 10A2, a third pixel-circuit column 10A3, and a fourth pixel-circuit column 10A4 sequentially arranged along the first direction X. To realize that in the i-th pixel circuit row 10H(i), the first pixel circuit 101 is electrically connected to the first color light-emitting element 201 of the first light-emitting element column 20A1, the second pixel circuit 102 is electrically connected to the second color light-emitting element 202 of the second light-emitting element column 20A2, the third pixel circuit 103 is electrically connected to the second color light-emitting element 202 of the fourth light-emitting element column 20A4, and the fourth pixel circuit 104 is electrically connected to the third color light-emitting element 203 of the third light-emitting element column 20A3, the connection lines may be made of conductive film layers. For example, the first pixel circuit 101 may be electrically connected to the first color light-emitting element 201 of the first light-emitting element column 20A1 through the first connection line LJ1, the second pixel circuit 102 may be electrically connected to the second color light-emitting element 202 of the second light-emitting element column 20A2 through the second connection line LJ2, the third pixel circuit 103 may be electrically connected to the second color light-emitting element 202 of the fourth light-emitting element column 20A4 through the third connection line LJ3, and the fourth pixel circuit 104 may be electrically connected to the third color light-emitting element 203 of the third light-emitting element column 20A3 through a fourth connection line LJ4.

Optionally, the first connection line LJ1 and the second connection line LJ2 may be anode signal lines. That is, the first pixel circuit 101 may be electrically connected to the first color light-emitting element 201 of the first light-emitting element column 20A1 through an anode signal line in a same layer the first pixel circuit 101, and the second pixel circuit 102 may be electrically connected to the second color light-emitting element 202 of the second light-emitting element column 20A2 through an anode signal line in a same layer as the second pixel circuit 102. The third connection line LJ3 and the fourth connection line LJ4 may be connection structures provided in different layers and connected through vias (alternatively, when the panel space is sufficient, the third connection line LJ3 and the fourth connection line LJ4 may be anode signal lines on a same layer as the anode). In this way, the third pixel circuit 103 may be electrically connected to the second color light-emitting element 202 of the fourth light-emitting element column 20A4, and the fourth pixel circuit 104 may be electrically connected to the third color light-emitting element 203 of the third light-emitting element column 20A3.

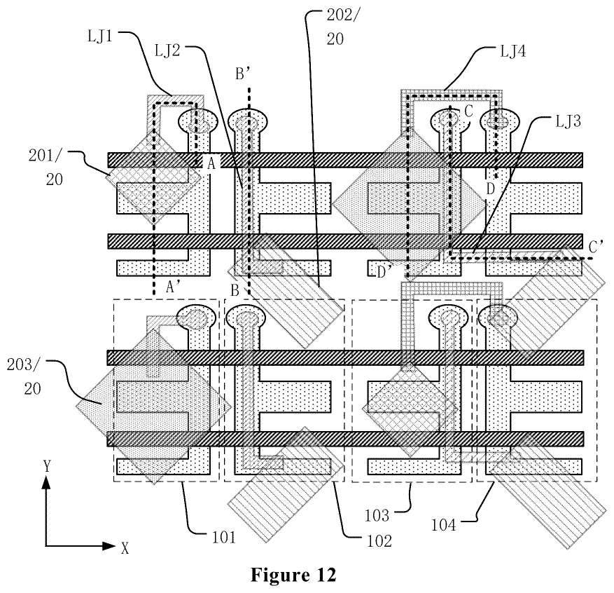

FIG. 12 illustrates a partially enlarged schematic diagram of the J2 region in FIG. 11, consistent with the disclosed embodiments of the present disclosure. Referring to FIGS. 1, 3, and 9-12, in one embodiment, the first pixel circuit 101 of the first pixel-circuit column 10A1 is electrically connected to the first color light-emitting element 201 of the first light-emitting element column 20A1 through the first connection line LJ1. The second pixel circuit 102 of the second pixel-circuit column 10A2 is electrically connected to the second color light-emitting element 202 of the second light-emitting element column 20A2 through the second connection line LJ2.

A light-emitting element column group 20A may be driven by a pixel-circuit column group 10A to emit light. Along the first direction X, the light-emitting element column group 20A includes a first light-emitting element column 20A1, a second light-emitting element column 20A2, a third light-emitting element column 20A3 and a fourth light-emitting element column 20A4, which are sequentially arranged. The pixel-circuit column group 10A includes a first pixel-circuit column 10A1, a second pixel-circuit column 10A2, a third pixel-circuit column 10A3, and a fourth pixel-circuit column 10A4, which are sequentially arranged. The first connection line LJ1 and the second connection line LJ2 may be relatively short. Since the third pixel circuit 103 of the third pixel-circuit column 10A3 is electrically connected to the second color light-emitting element 202 of the fourth light-emitting element column 20A4 through the third connection line LJ3, and the fourth pixel circuit 104 of the fourth pixel-circuit column 10A4 is electrically connected to the third color light-emitting element 203 of the third light-emitting element column 20A3 through the fourth connection line LJ4, the lengths of the third connection line LJ3 and the fourth connection line LJ4 may be relatively long. That is, the length of one or more of the first connection line LJ1 and the second connection line LJ2 may be less than the length of one or more of the third connection line LJ3 and the fourth connection line LJ4.

As such, the first connection line LJ1 and the second connection line LJ2 may be relatively short and may be directly made of a same film layer as the anode, that is, the anode signal line, to directly electrically connect the first pixel circuit 101 of the first pixel-circuit column 10A1 to the first color light-emitting element 201 of the first light-emitting element column 20A1, and to directly electrically connect the second pixel circuit 102 of the second pixel-circuit column 10A2 to the second color light-emitting element 202 of the second light-emitting element column 20A2.

The third connection line LJ3 and the fourth connection line LJ4 may be connection line structures in which a plurality of film layers is connected through vias and arranged in different layers (alternatively, when the panel space is sufficient, the third connection line LJ3 and the fourth connection line LJ4 may be anode signal lines on a same layer as the anode). With the third connection line LJ3 and the fourth connection line LJ4, the third pixel circuit 103 of the third pixel-circuit column 10A3 may be electrically connected to the second color light-emitting element 202 of the fourth light-emitting element column 20A4, and the fourth pixel circuit 104 of the fourth pixel-circuit column 10A4 may be electrically connected to the third color light-emitting element 203 of the third light-emitting element column 20A3.

It should be noted that FIG. 11 is only for illustrating that each connection line is connected to the pixel circuit. The connection positions between the pixel circuits and connection lines in FIG. 11 each do not represent the actual connection positions. In specific implementation, the positions where the light-emitting elements are connected to the transistors in the pixel circuits through the connecting lines may be set according to actual layout structures of the pixel circuits. In addition, the shapes and structures of the pixel circuits are only for illustration, and do not represent actual layout structures of the pixel circuits.

It may be understood that the layout shapes and routing methods of the first connection line LJ1, the second connection line LJ2, the third connection line LJ3, and the fourth connection line LJ4 in FIG. 11 and FIG. 12 are examples only. In a specific implementation, the layout shapes and routing methods may be set according to the actual film layer space of the panel, provided that one light-emitting element column group 20A is driven to emit light by one pixel-circuit column group 10A, the first pixel circuit 101 is electrically connected to the first color light-emitting element 201 of the first light-emitting element column 20A1, the second pixel circuit 102 is electrically connected to the second color light-emitting element 202 of the second light-emitting element column 20A2, the third pixel circuit 103 is electrically connected to the second color light-emitting element 202 of the fourth light-emitting element column 20A4, and the fourth pixel circuit 104 is electrically connected to the third color light-emitting element 203 of the third light-emitting element column 20A3.

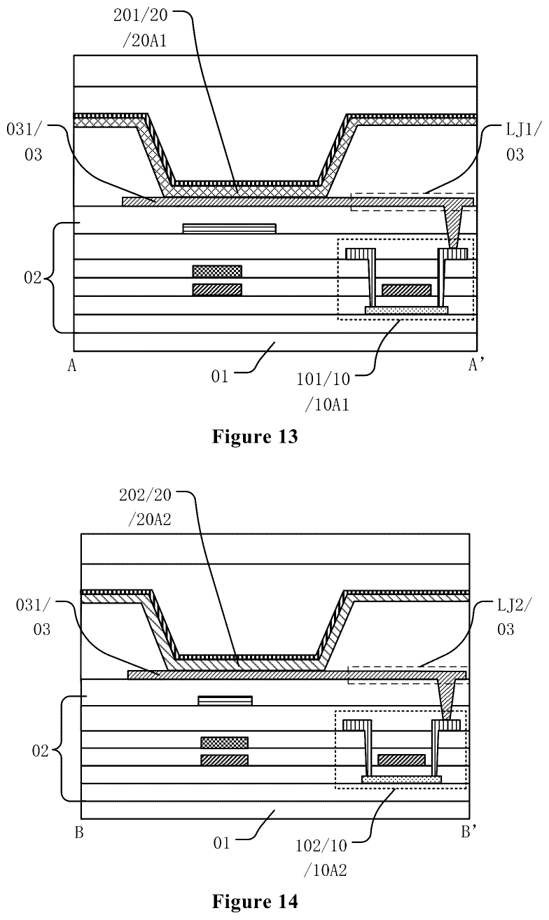

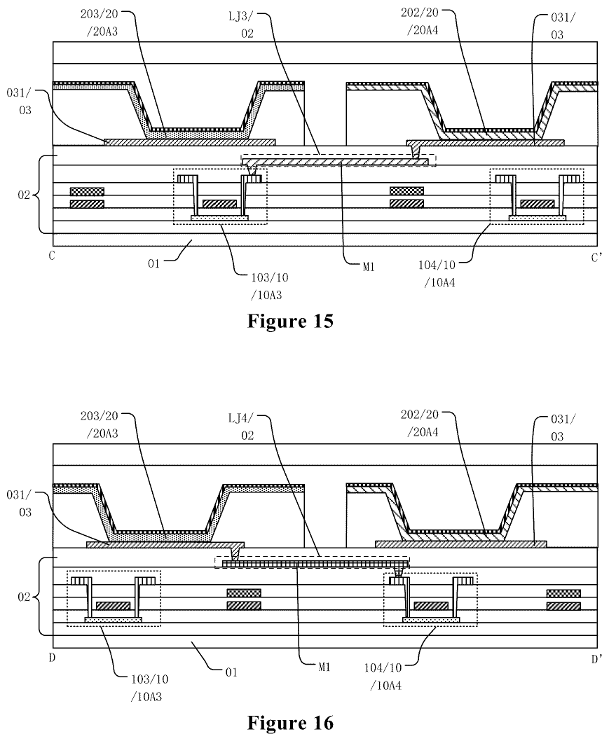

FIG. 13 illustrates a schematic structural diagram of a cross-section taken along the line A-A′ in FIG. 12, consistent with the disclosed embodiments of the present disclosure. FIG. 14 illustrates a schematic structural diagram of a cross-section taken along the line B-B′ in FIG. 12, consistent with the disclosed embodiments of the present disclosure. FIG. 15 illustrates a schematic structural diagram of a cross-section taken along the line C-C′ in FIG. 12, consistent with the disclosed embodiments of the present disclosure. FIG. 16 illustrates a schematic structural diagram of a cross-section taken along the line D-D′ in FIG. 12, consistent with the disclosed embodiments of the present disclosure. In one embodiment, referring to FIGS. 1, 3, 9-16, the display panel 000 includes a substrate 01, a driving array layer 02, and an anode layer 03. The anode layer 03 is disposed on a side of the driving array layer 02 away from the substrate 01.

The driving array layer 02 includes the pixel circuit 10. The anode layer 03 includes a plurality of anodes 031. The light-emitting element 20 is electrically connected to the pixel circuit 10 through the anode 031. Optionally, the light-emitting element 20 is electrically connected to the transistor in the pixel circuit 10 through the anode 031. One or more of the first connection line LJ1, the second connection line LJ2, the third connection line LJ3, and the fourth connection line LJ4 is located at the anode layer 03. Alternatively, one or more of the first connection line LJ1, the second connection line LJ2, the third connection line LJ3, and the fourth connection line LJ4 is located in the driving array layer 02.

In one embodiment, the film structure of the display panel 000 may include a substrate 01, and a drive array layer 02 and an anode layer 03 sequentially disposed on a side of the substrate 01. The substrate 01 is used as a carrier substrate for disposing other film layer structures of the display panel 000. Optionally, the substrate 01 of the display panel 000 may be made of a hard material such as glass, ceramic, or a combination thereof, or may be made of a flexible material such as polyimide (PI), polycarbonate (PC), polyethersulfone (PES), polyethylene terephthalate (PET), polyethylene naphthalate (PEN), or a combination thereof. The substrate 01 may be a transparent substrate, a semi-transparent substrate or an opaque substrate. The present disclosure does not limit a specific type of substrate.

The driving array layer 02 may be provided with transistors, capacitors, etc. of the pixel circuit 10 through a plurality of conductive film layers, and may also be provided with other driving lines and driving circuits. The layout structure of the driving array layer 02 is not elaborated here, and the details may be understood by referring to film layer structures of OLED display panels in existing technology. The anode layer 03 is configured to dispose the anode 031 electrically connected to the light-emitting element 20. The anode layer 03 may be made of various conductive materials. For example, the anode layer 03 may be made as a transparent anode or a reflective anode according to a specific purpose. When the anode layer 03 is made as a transparent anode, the material of the anode layer 03 may include indium tin oxide (ITO), indium zinc oxide (IZO), or a combination thereof. When the anode layer 03 is made as a reflective anode, the material of the anode layer 03 may include silver, magnesium, aluminum, or other metal mixtures. The present disclosure does not limit a specific material of the anode layer 03. The anode 031 corresponding to the light-emitting element 20 may be electrically connected to one or more transistor in the pixel circuit 10, to transmit the driving signal of the pixel circuit 10 to the anode 031, thereby driving the light-emitting element 20 to emit light.

It is understandable that the film structures of the display panel 000 in FIGS. 13-16 are examples only. In a specific implementation, the film structure of the display panel 000 includes but is not limited to the structures shown in FIGS. 13-16, and may also include a cathode layer, a packaging layer and other structures on the side of the light-emitting element 20 away from the substrate 01, which will not be elaborated here.

In one embodiment, one or more of the first connection line LJ1, the second connection line LJ2, the third connection line LJ3, and the fourth connection line LJ4 is disposed in the anode layer 03. As shown in FIGS. 13-14, the first connection line LJ1 and the second connection line LJ2 may be located at the anode layer 03. One transistor in the first pixel circuit 101 (such as the seventh transistor T7 in FIG. 7) may be electrically connected to the anode 031 corresponding to the first color light-emitting element 201. The anode 031 corresponding to the first color light-emitting element 201 of the first light-emitting element column 20A1 may be directly electrically connected to the first pixel circuit 101 of the first pixel-circuit column 10A1 through the first connection line LJ1 located on the anode layer 03. One transistor in the second pixel circuit 102 (such as the seventh transistor T7 in FIG. 7) may be electrically connected to the anode 031 corresponding to the second color light-emitting element 202. The anode 031 corresponding to the second color light-emitting element 202 of the second light-emitting element column 20A2 may be directly electrically connected to the second pixel circuit 102 of the second pixel-circuit column 10A2 through the second connection line LJ2 located on the anode layer 03.

As shown in FIGS. 15-16, the third connection line LJ3 and the fourth connection line LJ4 may disposed in a conductive film layer of the driving array layer 02. One transistor in the third pixel circuit 103 (such as the seventh transistor T7 in FIG. 7) may be electrically connected to the anode 031 corresponding to the second color light-emitting element 202. The anode 031 corresponding to the second color light-emitting element 202 of the fourth light-emitting element column 20A4 may be electrically connected to the third pixel circuit 103 of the third pixel-circuit column 10A3 through the third connection line LJ3 located on a certain conductive film layer of the drive array layer 02. One transistor in the fourth pixel circuit 104 (such as the seventh transistor T7 in FIG. 7) may be electrically connected to the anode 031 corresponding to the third color light-emitting element 203. The anode 031 corresponding to the third color light-emitting element 203 of the third light-emitting element column 20A3 may be electrically connected to the fourth pixel circuit 104 of the fourth pixel-circuit column 10A4 through the fourth connection line LJ4 located on a certain conductive film layer of the drive array layer 02.

In one embodiment, one or more of the first connection line LJ1, the second connection line LJ2, the third connection line LJ3, and the fourth connection line LJ4 is located at the anode layer 03, or one or more of the first connection line LJ1, the second connection line LJ2, the third connection line LJ3, and the fourth connection line LJ4 is located in the driving array layer 02. As such, the anode layer 03 may be used to directly set the first connection line LJ1 and the second connection line LJ2, and the fabrication process may be simplified. When the anode layer 03 has insufficient layout space, the third connection line LJ3 and the fourth connection line LJ4 may be laid out using the drive array layer 02 close to the anode layer 03. As such, short circuit problems caused by too many connection lines in the anode layer 03 may be avoided, and normal driving and display functions of the display panel may be realized.

Optionally, in one embodiment, in a same third connection line LJ3, at least a part of the segments may be located in the anode layer 03, and at least a part of the segments may be located in the driving array layer 02. Alternatively, among the plurality of third connection lines LJ3, at least a part of the third connection lines LJ3 may be located at the anode layer 03, and at least a part of the third connection lines LJ3 may be located at the drive array layer 02. In a same fourth connection line LJ4, at least a part of the segments may be located in the anode layer 03, and at least a part of the segments may be located in the driving array layer 02. Alternatively, among the plurality of fourth connection lines LJ4, at least a part of the fourth connection lines LJ4 may be located at the anode layer 03, and at least a part of the fourth connection lines LJ4 may be located at the drive array layer 02. The only requirement for the above configuration is to avoid short circuit problems between different connection lines in the film layer where the connection lines are located. The present disclosure does not limit specific film layers and routing shapes of the first connection line LJ1, the second connection line LJ2, the third connection line LJ3, and the fourth connection line LJ4. During a specific implementation, the layout of the connection lines may be made based on the remaining space of the film layers.

Optionally, as shown in FIGS. 13-16, in one embodiment, the driving array layer 02 of the display panel 000 includes a first metal layer M1, and no other conductive layer is disposed between the first metal layer M1 and the anode layer 03. That is, the first metal layer M1 is a conductive film layer in the driving array layer 02 that is closest to the anode layer 03. At least a part of the third connection line LJ3 may be disposed on the first metal layer M1, or at least a part of the fourth connection line LJ4 may be disposed on the first metal layer M1, such that the transistor of the pixel circuit 10 may be connected to the third connection line LJ3 or the fourth connection line LJ4 through a via. When the third connection line LJ3 or the fourth connection line LJ4 is electrically connected to the anode 031 of the anode layer 03 through a via, the via may not be too deep, avoiding the via being too deep to affect the manufacturing process and signal transmission performance. Accordingly, the signal transmission stability of the third connection line LJ3 and the fourth connection line LJ4 may be improved, and the display quality may be improved.

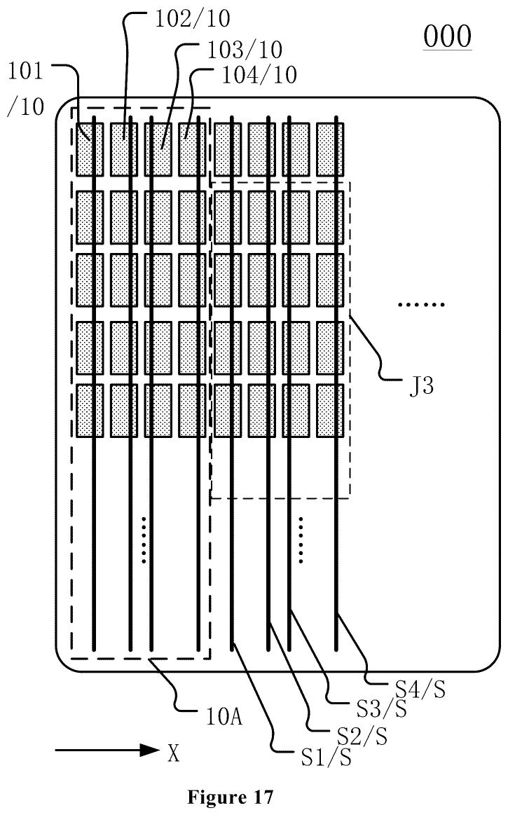

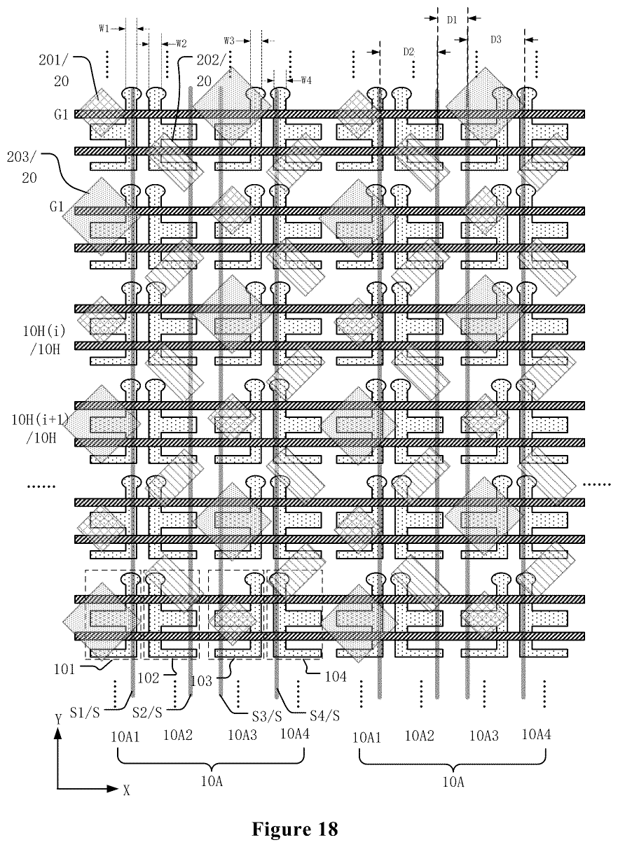

FIG. 17 illustrates a schematic diagram of another planar structure of a display panel consistent with the disclosed embodiments of the present disclosure. FIG. 18 illustrates a partially enlarged schematic diagram of the J3 region of FIG. 17. To clearly illustrate the structure, FIG. 17 uses blocks to represent the pixel circuits, and FIG. 18 is filled with different transparency degrees. Referring to FIGS. 17 and 18, in one embodiment, the display panel 000 includes a plurality of data lines S. The plurality of data lines S includes a first data line S1, a second data line S2, a third data line S3, and a fourth data line S4 arranged along the first direction X. The first data line S1 is electrically connected to the first pixel circuit 101, the second data line S2 is electrically connected to the second pixel circuit 102, the third data line S3 is electrically connected to the third pixel circuit 103, and the fourth data line S4 is electrically connected to the fourth pixel circuit 104.

Along the first direction X, the second data line S2 and the third data line S3 are adjacently arranged with a spacing of D1. The first data line S1 and the second data line S2 are adjacently arranged with a spacing of D2, and the third data line S3 and the fourth data line S4 are adjacently arranged with a spacing of D3, where D2>D1, D3>D1.

Optionally, in the pixel circuit 10, the data line S may be electrically connected to one electrode of the third transistor T3 shown in FIG. 7. In the threshold compensation and data writing stage when driving the display panel 000, the third scanning signal terminal SCP inputs a low-level third scanning signal to control the third transistor T3 to be turned on. The second scanning signal terminal SCN2 inputs a high-level second scanning signal to control the first transistor T1 to be turned on. The data voltage VDATA provided by the data line S of the display panel 000 is transmitted to the gate of the driving transistor DT through the third transistor T3, the driving transistor DT and the first transistor T1.

In one embodiment, the display panel 000 may be disposed with a plurality of data lines S. The data lines S are configured to provide data voltage signals to the pixel circuits 10. The plurality of data lines S at least includes a first data line S1, a second data line S2, a third data line S3, and a fourth data line S4 that are arranged along a first direction X. It may be understood that the first data line S1, the second data line S2, the third data line S3, and the fourth data line S4 are configured to provide data voltage signals for the first pixel-circuit column 10A1, the second pixel-circuit column 10A2, the third pixel-circuit column 10A3, and the fourth pixel-circuit column 10A4 included in the pixel-circuit column group 10A.

Optionally, when the first data line S1 is electrically connected to the first pixel circuit 101, and the first pixel circuit 101 drives the first color light-emitting element 201 or the third color light-emitting element 203, the first data line S1 is configured to provide a data voltage signal when the first color light-emitting element 201 emits light or a data voltage signal when the third color light-emitting element 203 emits light. When the second data line S2 is electrically connected to the second pixel circuit 102, and the second pixel circuit 102 drives the second color light-emitting element 202, the second data line S2 is configured to provide a data voltage signal when the second color light-emitting element 202 emits light. When the third data line S3 is electrically connected to the third pixel circuit 103, and the third pixel circuit 103 drives the second color light-emitting element 202, the third data line S2 is configured to provide a data voltage signal when the second color light-emitting element 202 emits light. When the fourth data line S4 is electrically connected to the fourth pixel circuit 104, and the fourth pixel circuit 104 drives the third color light-emitting element 203 or the first color light-emitting element 201, the fourth data line S4 is configured to provide a data voltage signal when the first color light-emitting element 201 emits light or a data voltage signal when the third color light-emitting element 203 emits light.

Compared with the second data line S2 and the third data line S3, the first data line S1 and the fourth data line S4 each provide data voltage signals for the third color light-emitting element 203 or the first color light-emitting element 201. The second data line S2 and the third data line S3 each provide data voltage signals for the second color light-emitting element 202. As such, in one embodiment, along the first direction X, that is, along the direction in which the first data line S1, the second data line S2, the third data line S3, and the fourth data line S4 are arranged in sequence, the spacing D1 between the second data line S2 and the third data line S3 that are adjacent to each other is set to be smaller. The spacing D2 between the first data line S1 and the second data line S2 and the spacing D3 between the third data line S3 and the fourth data line S4 are set to be larger. That is, the spacing D1 between the second data line S2 and the third data line S3 is smaller than the spacing D2 between the first data line S1 and the second data line S2. The spacing D1 between the second data line S2 and the third data line S3 is smaller than the spacing D3 between the third data line S3 and the fourth data line S4. In other words, the first data line S1 and the fourth data line S4 may be farther away from the second data line S2 and the third data line S3. As such, two data lines that transmit different data voltage signals to different color light-emitting elements may be spaced farther apart. Accordingly, mutual interference between data voltage signals of light-emitting elements of different colors may be avoided, and display quality may be improved.

Optionally, when the first data line S1 is electrically connected to the first pixel circuit 101, and the first pixel circuit 101 drives the first color light-emitting element 201 or the third color light-emitting element 203, the first data line S1 is configured to provide a data voltage signal when the first color light-emitting element 201 emits light or a data voltage signal when the third color light-emitting element 203 emits light. That is, when the first color light-emitting element 201 and the third color light-emitting element 203 of the first light-emitting element column 20A1 emits light emits light, the first data line S1 needs to switch the data voltage signals (for example, jumping between the data voltage signals required by the R/B light-emitting elements), such that the first pixel circuit 101 may respectively drive the first color light-emitting element 201 and the third color light-emitting element 203 of the first light-emitting element column 20A1 to emit light.

When the second data line S2 is electrically connected to the second pixel circuit 102, and the second pixel circuit 102 drives the second color light-emitting element 202, the second data line S2 is configured to provide a data voltage signal when the second color light-emitting element 202 emits light. That is, when the second color light-emitting element 202 in the second light-emitting element column 20A2 emits light, the second pixel circuit 102 may drive the second color light-emitting element 202 of the second light-emitting element column 20A2 to emit light without switching the data voltage signal (for example, the data voltage signal required by the G light-emitting element).

When the third data line S3 is electrically connected to the third pixel circuit 103, and the third pixel circuit 103 drives the second color light-emitting element 202, the third data line S2 is configured to provide a data voltage signal when the second color light-emitting element 202 emits light. That is, when the second color light-emitting element 202 of the fourth light-emitting element column 20A4 emits light, the third pixel circuit 103 may drive the second color light-emitting element 202 of the fourth light-emitting element column 20A4 to emit light without switching the data voltage signal (for example, the data voltage signal required by the G light-emitting element).

When the fourth data line S4 is electrically connected to the fourth pixel circuit 104, and the fourth pixel circuit 104 drives the third color light-emitting element 203 or the first color light-emitting element 201, the fourth data line S4 is configured to provide a data voltage signal when the first color light-emitting element 201 emits light or a data voltage signal when the third color light-emitting element 203 emits light. That is, when the first color light-emitting element 201 and the third color light-emitting element 203 of the third light-emitting element column 20A3 emit light, the fourth data line S4 needs to switch the data voltage signal (for example, jumping between the data voltage signals required by the R/B light-emitting element), such that, the fourth pixel circuit 104 may respectively drive the first color light-emitting element 201 and the third color light-emitting element 203 of the third light-emitting element column 20A3 to emit light.

As described above, during the driving process of the display panel 000, the first data line S1 and the fourth data line S4 each need to switch the data voltage signal to realize that a same data line drives light-emitting elements of different colors to emit light. The second data line S2 and the third data line S3 may drive the light-emitting elements of a same color to emit light without switching the data voltage signal. As such, in one embodiment, along the first direction X, that is, along the direction in which the first data line S1, the second data line S2, the third data line S3, and the fourth data line S4 are arranged in sequence, the spacing D1 between the second data line S2 and the third data line S3 that are adjacent to each other may be a bit smaller, and the spacing D2 between the first data line S1 and the second data line S2 and the spacing D3 between the third data line S3 and the fourth data line S4 may be a bit larger. That is, the spacing D1 between the second data line S2 and the third data line S3 may be smaller than the spacing D2 between the first data line S1 and the second data line S2, and the spacing D1 between the second data line S2 and the third data line S3 may be smaller than the distance D3 between the third data line S3 and the fourth data line S4.

As such, the first data line S1 that needs to switch the data voltage signal may be farther from the second data line S2, and the fourth data line S4 that needs to switch the data voltage signal may be farther from the third data line S3. Accordingly, the data voltage signals of the first data line S1 and the fourth data line S4 may be prevented from being coupled to the second data line S2 and the third data line S3 thereby affecting the signal transmission performance of the second data line S2 and the third data line S3. As a result, the display quality may be improved. In addition, the second data line S2 and the third data line S3 that do not need to switch the data voltage signal may be closer to each other. Even when the first data line S1 is farther from the second data line S2, and the fourth data line S4 is farther from the third data line S3, the space in the first direction X occupied by the four data lines S, namely, the first data line S1, the second data line S2, the third data line S3, and the fourth data line S4, may not affected. Accordingly, the panel may have enough space to lay out the plurality of data lines, and the wiring process may be simplified.

It may be understood that, in one embodiment, the data lines S may be disposed in one or two film layers in the driving array layer. The plurality of data lines S may be disposed in different layers or in a same layer. Details of disposing the data lines will not be elaborated here, and reference may be made to the film layer layout method of the data lines in the existing technology.

It should be noted that the data lines S in FIG. 17 and FIG. 18 are exemplary only. In a specific implementation, the layout of the data lines S may be fine-tuned in shape according to the actual space of the panel, provided that the overall extension direction of the data lines S is the vertical direction as shown in FIGS. 17 and 18, such that the data lines S may be electrically connected with a driving chip that may be subsequently bound to the display panel 000.

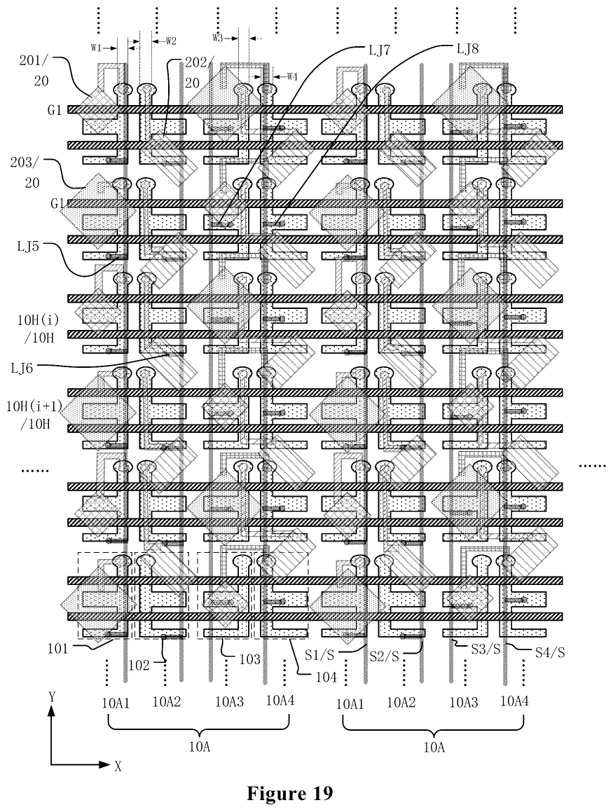

FIG. 19 illustrates another partially enlarged schematic diagram of the J3 region of FIG. 17, consistent with the disclosed embodiments of the present disclosure. To clearly illustrate the structure, FIG. 19 is filled with different transparency degrees. Referring to FIGS. 7 and 17-19, in one embodiment, the first data line S1 may be electrically connected to an electrode of a transistor in the first pixel circuit 101, such as the third transistor T3 in FIG. 7, through a fifth connection line LJ5. The second data line S2 may be electrically connected to an electrode of a transistor in the second pixel circuit 102, such as the third transistor T3 in FIG. 7, through a sixth connection line LJ6. The third data line S3 may be electrically connected to an electrode of a transistor in the third pixel circuit 103, such as the third transistor T3 in FIG. 7, through a seventh connection line LJ7. The fourth data line S4 may be electrically connected to an electrode of a transistor in the fourth pixel circuit 104, such as the third transistor T3 in FIG. 7, through an eighth connection line LJ8. As such, the transmission of the data voltage signals between the pixel circuit 10 and the data line S may be achieved.

Optionally, the film layers of the fifth connection line LJ5, the sixth connection line LJ6, the seventh connection line LJ7, and the eighth connection line LJ8 may be arranged according to the actual space of the panel. For example, one or more of the fifth connection line LJ5, the sixth connection line LJ6, the seventh connection line LJ7, and the eighth connection line LJ8 may be in a same layer as the data lines S; or at least a part of the fifth connection line LJ5, the sixth connection line LJ6, the seventh connection line LJ7, and the eighth connection line LJ8 may be in a different layer from the data line S. The present disclosure does not limit a specific arrangement of the film layers of the fifth connection line LJ5, the sixth connection line LJ6, the seventh connection line LJ7, and the eighth connection line LJ8, provided that the electrical connection effects between the pixel circuits and the data lines may be achieved, and short circuits may be avoided.

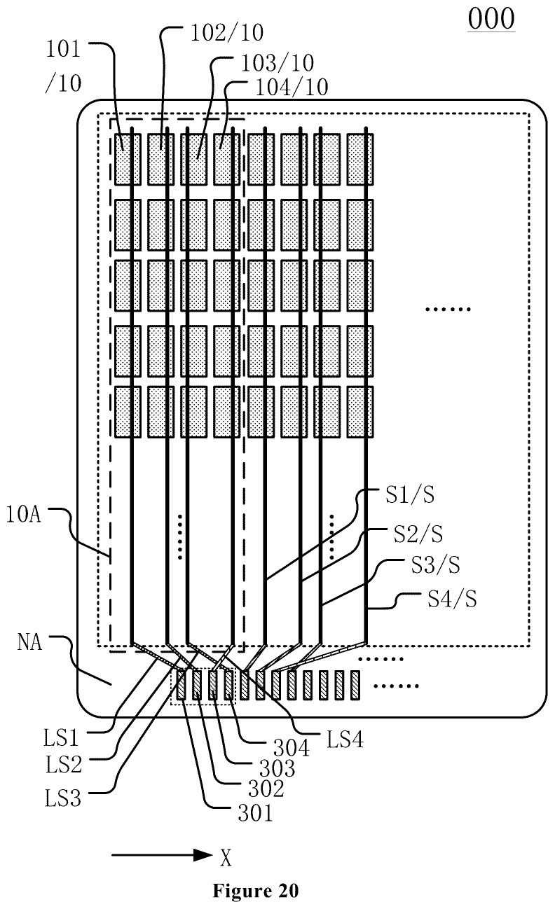

FIG. 20 illustrates a schematic diagram of another planar structure of a display panel consistent with the disclosed embodiments of the present disclosure. In some optional embodiments, referring to FIGS. 7, and 17-20, the non-display area NA of the display panel 000 includes a plurality of first binding pads 301, a plurality of second binding pads 302, a plurality of third binding pads 303, and a plurality of fourth binding pads 304. The first binding pad 301, the second binding pad 302, the third binding pad 303, and the fourth binding pad 304 are sequentially arranged along the first direction X.

The first data line S1 is electrically connected to the first binding pad 301 through a first fan-out line LS1. The second data line S2 is electrically connected to the second binding pad 302 through a second fan-out line LS2. The third data line S3 is electrically connected to the fourth binding pad 304 through a third fan-out line LS3. The fourth data line S4 is electrically connected to the third binding pad 303 through a fourth fan-out line LS4.

The third fan-out line LS3 and the fourth fan-out line LS4 are arranged at different layers. The orthographic projection of the third fan-out line LS3 on the plane where the display panel 000 is located overlaps with the orthographic projection of the fourth fan-out line LS4 on the plane where the display panel 000 is located.

In one embodiment, the display panel 000 may be subsequently bound to a driving chip or a flexible circuit board, such that the driving chip or the flexible circuit board may provide a driving signal for the display panel 000. Binding pads may be disposed in the non-display area NA of the display panel 000, and generally in the non-display area NA at the bottom frame of the display panel 000. Through the binding pads, the binding electrical connection between the display panel 000 and the driving chip or flexible circuit board may be realized.

Specifically, the non-display area NA of the display panel 000 may include a plurality of first binding pads 301, a plurality of second binding pads 302, a plurality of third binding pads 303, and a plurality of fourth binding pads 304, which are configured to provide data voltage signals for the plurality of data lines S. The first binding pad 301, the second binding pad 302, the third binding pad 303, and the fourth binding pad 304 are sequentially arranged along the first direction X. The first binding pad 301, the second binding pad 302, the third binding pad 303, and the fourth binding pad 304 correspond to the first data line S1, the second data line S2, the third data line S3, and the fourth data line S4, respectively. The first data line S1 is electrically connected to the first binding pad 301 through the first fan-out line LS1. The second data line S2 is electrically connected to the second binding pad 302 through the second fan-out line LS2. The third data line S3 is electrically connected to the fourth binding pad 304 through the third fan-out line LS3. The fourth data line S4 is electrically connected to the third binding pad 303 through the fourth fan-out line LS4.

In existing technology, in driving chips or flexible circuit boards that have been developed and used, and have relatively mature technology, pins that provide data voltage signals are generally arranged as follows: the R/B pin providing a jumping data voltage signal to drive the red light-emitting element or the blue light-emitting element respectively, the G pin providing a non-jumping data voltage signal to drive the green light-emitting element, the R/B pin providing a jumping data voltage signal to drive the red light-emitting element or the blue light-emitting element respectively, the G pin providing a non-jumping data voltage signal to drive the green light-emitting element, . . . and so on.

In one embodiment, the first data line S1 is electrically connected to the first pixel circuit 101, and the first pixel circuit 101 drives the first color light-emitting element 201 or the third color light-emitting element 203, that is, the first data line S1 needs to switch the data voltage signal. The second data line S2 is electrically connected to the second pixel circuit 102, and the second pixel circuit 102 drives the second color light-emitting element 202, that is, the second data line S2 does not need to switch the data voltage signal. The third data line S3 is electrically connected to the third pixel circuit 103, and the third pixel circuit 103 drives the second color light-emitting element 202, that is, the third data line S3 does not need to switch the data voltage signal. The fourth data line S4 is electrically connected to the fourth pixel circuit 104, and the fourth pixel circuit 104 drives the third color light-emitting element 203 or the first color light-emitting element 201, that is, the fourth data line S4 needs to switch the data voltage signal. In this case, the driving chips or flexible circuit boards that are developed and used in the related technology and have relatively mature technology may still be used. The third fan-out line LS3 and the fourth fan-out line LS4 may be arranged in different layers. The orthographic projection of the third fan-out line LS3 on the plane where the display panel 000 is located may overlap with the orthographic projection of the fourth fan-out line LS4 on the plane where the display panel 000 is located. In this way, there is no need to redevelop driving chips or flexible circuit boards, and it is only necessary to make the third fan-out line LS3 and the fourth fan-out line LS4 overlap in the direction perpendicular to the plane where the display panel is located. That is, by crossing the third fan-out line LS3 and the fourth fan-out line LS4 at different layers, the corresponding electrical connection may be achieved without changing the order of the pins on the driving chip or the flexible circuit board. Accordingly, the development and design costs may be reduced.

In one embodiment, the third fan-out line LS3 and the fourth fan-out line LS4 are disposed at different layers. The third fan-out line LS3 and the fourth fan-out line LS4 may be respectively located at two different conductive layers in the driving array layer, such as a gate metal layer where a gate of a thin film transistor is located and a capacitor metal layer where an electrode of a capacitor is located. Alternatively, the third fan-out line LS3 and the fourth fan-out line LS4 may be disposed at two other different conductive layers, which is not limited by the present disclosure.

It should be noted that the arrangement structure of the plurality of binding pads shown in FIG. 20 is exemplary only. In a specific implementation, the plurality of binding pads in the non-display area NA may not be arranged straightly along the first direction X, but may be arranged in an undulating manner according to the space of the non-display area NA. The present disclosure does not limit a specific arrangement structure, provided that the plurality of binding pads is arranged along the first direction X overall. For details, reference may be made to the pad design when a driving chip or a flexible circuit board is bound to a display panel in existing technology.

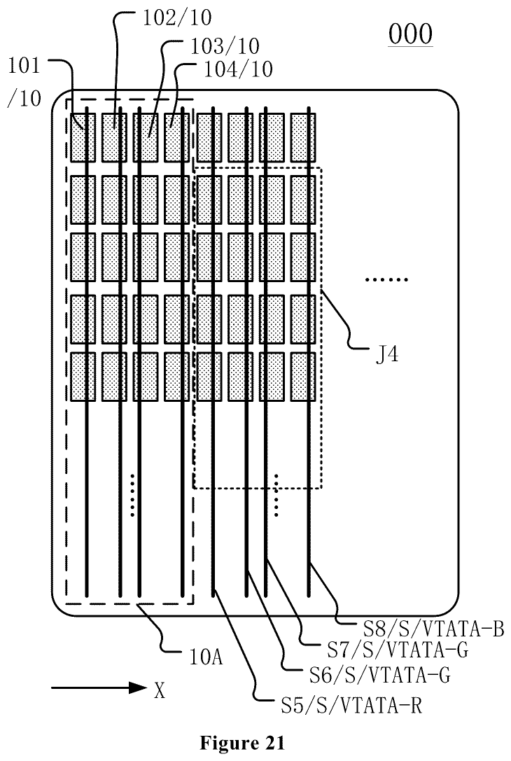

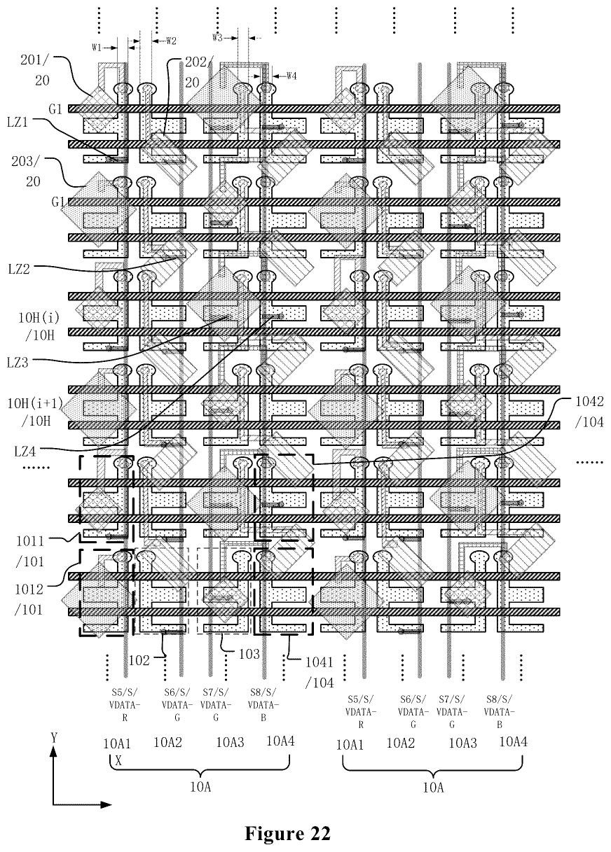

FIG. 21 illustrates a schematic diagram of another planar structure of a display panel consistent with the disclosed embodiments of the present disclosure. FIG. 22 illustrates a partially enlarged schematic diagram of the J4 region of FIG. 21, consistent with the disclosed embodiments of the present disclosure. To clearly illustrate the structure, FIG. 21 uses blocks to represent pixel circuits, and FIG. 22 is filled with different transparency degrees. In one embodiment, referring to FIGS. 7, 21 and 22, the display panel 000 includes a plurality of data lines S. The data line S is electrically connected to the pixel circuit 10. Optionally, in the pixel circuit 10, the transistor electrically connected to the data line S may be the third transistor T3 shown in FIG. 7. In the threshold compensation and data writing stage when driving the display panel 000, the third scanning signal terminal SCP inputs a low-level third scanning signal to control the third transistor T3 to be turned on. The second scanning signal terminal SCN2 inputs a high-level second scanning signal to control the first transistor T1 to be turned on. The data voltage VDATA provided by the data line S of the display panel 000 may be transmitted to the gate of the driving transistor DT through the third transistor T3, the driving transistor DT and the first transistor T1.

In one embodiment, the light-emitting elements 20 driven by a plurality of pixel circuits 10 electrically connected to a same data line S may have a same color. That is, one data line S may only transmit the data voltage signal required by the corresponding light-emitting elements 20 of one color. The data voltage signal on the data line S does not need to jump, such that a stable data voltage signal may be transmitted on each data line S. Accordingly, the power consumption of the driving chip or the flexible circuit board subsequently bound to the display panel and the display panel may be reduced, and the overall driving power consumption may thus be reduced.

Optionally, the plurality of data lines S may include a fifth data line S5, a sixth data line S6, a seventh data line S7 and an eighth data line S8 that are arranged along the first direction X. The fifth data line S5 is configured to provide a data voltage signal VDATA-R to the pixel circuit 10 electrically connected to the first color light-emitting element 201. The sixth data line S6 is configured to provide a data voltage signal VDATA-G for the pixel circuit 10 electrically connected to the second color light-emitting element 202. The seventh data line S7 is configured to provide a data voltage signal VDATA-G for the pixel circuit 10 electrically connected to the second color light-emitting element 202. The eighth data line S8 is configured to provide a data voltage signal VDATA-B to the pixel circuit 10 electrically connected to the third color light-emitting element 203.

The plurality of first pixel circuits 101 of the first pixel-circuit column 10A1 includes a first sub-pixel circuit 1011 and a second sub-pixel circuit 1012. The first sub-pixel circuit 1011 is electrically connected to the first color light-emitting element 201 of the first light-emitting element column 20A1. The second sub-pixel circuit 1012 is electrically connected to the third color light-emitting element 203 of the first light-emitting element column 20A1. The fifth data line S5 is electrically connected to the first sub-pixel circuit 1011 in the first pixel-circuit column 10A1.

The sixth data line S6 is electrically connected to the second pixel circuit 102 in the second pixel-circuit column 10A2. The second pixel circuit 102 in the second pixel-circuit column 10A2 is electrically connected to the second color light-emitting element 202 in the second light-emitting element column 20A2.

The seventh data line S7 is electrically connected to the third pixel circuit 103 in the third pixel-circuit column 10A3. The third pixel circuit 103 in the third pixel-circuit column 10A3 is electrically connected to the second color light-emitting element 202 in the fourth light-emitting element column 20A4.

The plurality of fourth pixel circuits 104 of the fourth pixel-circuit column 10A4 includes a third sub-pixel circuit 1041 and a fourth sub-pixel circuit 1042. The third sub-pixel circuit 1041 is electrically connected to the first color light-emitting element 201 of the third light-emitting element column 20A3. The fourth sub-pixel circuit 1042 is electrically connected to the third color light-emitting element 203 of the third light-emitting element column 20A3. The eighth data line S8 is electrically connected to the fourth sub-pixel circuit 1042 in the fourth pixel-circuit column 10A4.

One embodiment, in the pixel-circuit column group 10A including four pixel-circuit columns adjacent in the first direction X, the first pixel circuit 101 drives the first color light-emitting element 201 or the third color light-emitting element 203, the second pixel circuit 102 drives the second color light-emitting element 202, the third pixel circuit 103 drives the second color light-emitting element 202, and the fourth pixel circuit 104 drives the third color light-emitting element 203 or the first color light-emitting element 201. When the color of the light-emitting element driven by the third pixel circuit 103 is changed, and the color of the light-emitting element driven by the fourth pixel circuit 104 is changed, to ease the effect of color deviation, the arrangement structure of the data lines S may also be adjusted to achieve that the light-emitting elements 20 driven by the plurality of pixel circuits 10 electrically connected to a same data line S have a same color. Accordingly, the increase of power consumption caused by the jump of the signals transmitted on the data lines S may be avoided, and the overall driving power consumption may thus be reduced.

In addition, the fifth data line S5 is only configured to provide the data voltage signal VDATA-R for the pixel circuit 10 electrically connected to the first color light-emitting element 201, the sixth data line S6 is only configured to provide the data voltage signal VDATA-G for the pixel circuit 10 electrically connected to the second color light-emitting element 202, the seventh data line S7 is only configured to provide a data voltage signal VDATA-G for the pixel circuit 10 electrically connected to the second color light-emitting element 202, and the eighth data line S8 is only configured to provide the data voltage signal VDATA-B for the pixel circuit 10 electrically connected to the third color light-emitting element 203. The fifth data line S5, the sixth data line S6, the seventh data line S7, and the eighth data line S8 are sequentially arranged along the first direction X. The first pixel circuit 101, the second pixel circuit 102, the third pixel circuit 103, and the fourth pixel circuit 104 are sequentially arranged along the first direction X. In a same pixel circuit row, the first pixel circuit 101 drives the first color light-emitting element 201, the second pixel circuit 102 drives the second color light-emitting element 202, the third pixel circuit 103 drives the second color light-emitting element 202, and the fourth pixel circuit 104 drives the third color light-emitting element 203.

As such, when the fifth data line S5 is electrically connected to the first sub-pixel circuit 1011 in the first pixel-circuit column 10A1, the connection sub-line may be set to be relatively short. The connection sub-line may not need to extend to the positions of other pixel circuits in adjacent or other pixel-circuit columns. When the sixth data line S6 is electrically connected to the second pixel circuit 102 in the second pixel-circuit column 10A2, the connection sub-line may be set to be relatively short. The connection sub-line may not need to extend to the positions of other pixel circuits in adjacent or other pixel-circuit columns. When the seventh data line S7 is electrically connected to the third pixel circuit 103 in the third pixel-circuit column 10A3, the connection sub-line may be set to be relatively short. The connection sub-line may not need to extend to the positions of other pixel circuits in adjacent or other pixel-circuit columns. When the eighth data line S8 is electrically connected to the fourth sub-pixel circuit 1042 in the fourth pixel-circuit column 10A4, the connection sub-line may also be set to be relatively short. The connection sub-line may not need to extend to the positions of other pixel circuits in adjacent or other pixel-circuit columns. In this configuration, a data line of a current column is electrically connected to a pixel circuit of a corresponding current column. As such, the data line of the current column may be electrically connected to the pixel circuit of the corresponding current column by directly drilling a via in a direction perpendicular to the plane where the display panel is located. Accordingly, the parasitic capacitance on the data line S may be optimized and reduced, and the display effect may thus be improved.

Optionally, in one embodiment, the light-emitting elements 20 driven by the plurality of pixel circuits 10 electrically connected to a same data line S have a same color. The fifth data line S5 is configured to provide the data voltage signal VDATA-R to the pixel circuit 10 electrically connected to the first color light-emitting element 201. The sixth data line S6 is configured to provide the data voltage signal VDATA-G for the pixel circuit 10 electrically connected to the second color light-emitting element 202. The seventh data line S7 is configured to provide the data voltage signal VDATA-G for the pixel circuit 10 electrically connected to the second color light-emitting element 202. The eighth data line S8 is configured to provide the data voltage signal VDATA-B to the pixel circuit 10 electrically connected to the third color light-emitting element 203.

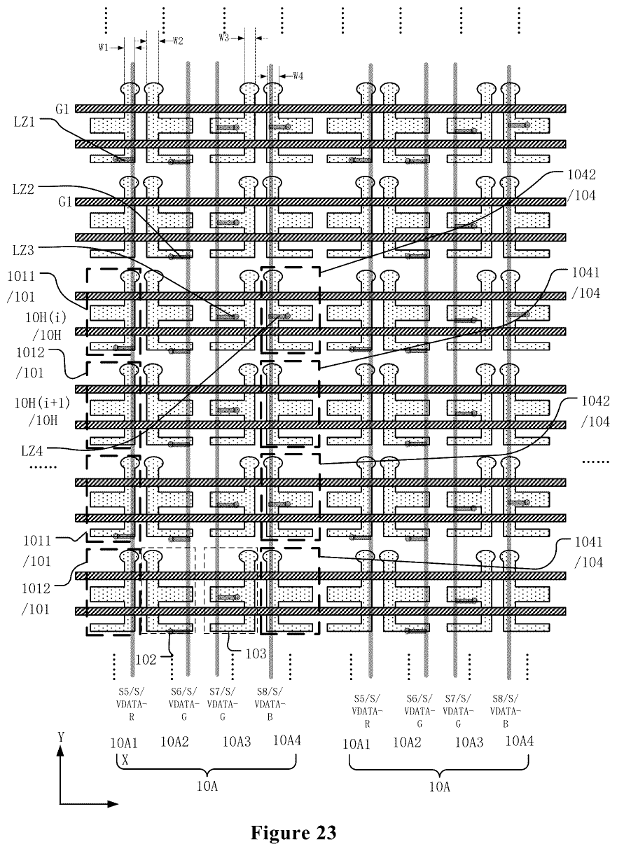

In one embodiment, the sixth data line S6 and the seventh data line S7 each provide data voltage signals for the second color light-emitting element 202. The fifth data line S5 provides data voltage signals for the first color light-emitting element 201, and the eighth data line S8 provides data voltage signals for the third color light-emitting element 203. As such, along the first direction X, that is, along the direction in which the fifth data line S5, the sixth data line S6, the seventh data line S7, and the eighth data line S8 are sequentially arranged, the spacing between the sixth data line S6 and the seventh data line S7 adjacent to each other may be a bit smaller, and the spacing between the fifth data line S5 and the sixth data line S6 and the spacing between the seventh data line S7 and the eighth data line S8 may be a bit larger (as shown in FIGS. 22 and 23). That is, the spacing between the sixth data line S6 and the seventh data line S7 may be smaller than the spacing between the fifth data line S5 and the sixth data line S6. The distance between the sixth data line S6 and the seventh data line S7 may be smaller than the distance between the seventh data line S7 and the eighth data line S8. In other words, the sixth data line S6 and the seventh data line S7 may be farther away from the fifth data line S5 and the eighth data line S8. As such, two data lines that transmit different data voltage signals to different color light-emitting elements may be spaced farther apart. Accordingly, mutual interference between data voltage signals of light-emitting elements of different colors may be reduced, and display quality may be improved.

Optionally, in one embodiment, the fifth data line S5 is electrically connected to the first sub-pixel circuit 1011 in the first pixel-circuit column 10A1 through a first connection portion. The sixth data line S6 is electrically connected to the second pixel circuit 102 in the second pixel-circuit column 10A2 through a second connection portion. The seventh data line S7 is electrically connected to the third pixel circuit 103 in the third pixel-circuit column 10A3 through a third connection portion. The eighth data line S8 is electrically connected to the fourth sub-pixel circuit 1042 in the fourth pixel-circuit column 10A4 through a fourth connection portion. The first connection portion, the second connection portion, the third connection portion, and the fourth connection portion may be connection sub-lines disposed in the conductive film layers of the display panel, vias opened between different conductive layers, or combinations of connection sub-lines and vias.

FIG. 23 illustrates a schematic diagram of a corresponding layout of the pixel circuit and the data line in FIG. 22, consistent with the disclosed embodiments of the present disclosure. To clearly illustrate the structure, the light-emitting elements in FIG. 23 are omitted, and FIG. 23 is filled with different transparency degrees. Optionally, as an example, the first connection portion, the second connection portion, the third connection portion, and the fourth connection portion are taken as connection sub-lines. As shown in FIGS. 21-23, in one embodiment, the fifth data line S5 is electrically connected to the first sub-pixel circuit 1011 in the first pixel-circuit column 10A1 through the first sub-line LZ1. The sixth data line S6 is electrically connected to the second pixel circuit 102 in the second pixel-circuit column 10A2 through the second sub-line LZ2. The seventh data line S7 is electrically connected to the third pixel circuit 103 in the third pixel-circuit column 10A3 through the third sub-line LZ3. The eighth data line S8 is electrically connected to the fourth sub-pixel circuit 1042 in the fourth pixel-circuit column 10A4 through the fourth sub-line LZ4.

In one embodiment, the data lines of the current column are electrically connected to the pixel circuits of the corresponding current column. When the fifth data line S5 is electrically connected to the first sub-pixel circuit 1011 in the first pixel-circuit column 10A1, the first sub-line LZ1 may be set to be relatively short. The first sub-line LZ1 does not need to extend to other pixel circuit positions in adjacent or other pixel-circuit columns. When the sixth data line S6 is electrically connected to the second pixel circuit 102 in the second pixel-circuit column 10A2, the second sub-line LZ2 may be set to be relatively short. The second sub-line LZ2 does not need to extend to other pixel circuit positions in adjacent or other pixel-circuit columns. When the seventh data line S7 is electrically connected to the third pixel circuit 103 in the third pixel-circuit column 10A3, the third sub-line LZ3 may be set to be relatively short. The third sub-line LZ3 does not need to extend to other pixel circuit positions in adjacent or other pixel-circuit columns. When the eighth data line S8 is electrically connected to the fourth sub-pixel circuit 1042 in the fourth pixel-circuit column 10A4, the fourth sub-line LZ4 may be set to be relatively short. The fourth sub-line LZ4 does not need to extend to other pixel circuit positions in adjacent or other pixel-circuit columns. In this way, the electrical connection between the data lines of a current column and the pixel circuits of a corresponding current column may be realized. The layout space of the first sub-line LZ1, the second sub-line LZ2, the third sub-line LZ3, and the fourth sub-line LZ4 may be saved. The parasitic capacitance on the data lines S may be optimized and reduced, and the display effect may be improved.

Optionally, since the first sub-line LZ1, the second sub-line LZ2, the third sub-line LZ3, and the fourth sub-line LZ4 each are relatively short, one or more of the first sub-line LZ1, the second sub-line LZ2, the third sub-line LZ3, and the fourth sub-line LZ4 may be in a same layer as the data line S. That is, a sub-line may be directly drawn from the data line S to realize the electrical connection with the pixel circuit 10. As such, the number of vias drilled when the sub-line and the data line S are in different layers may be reduced, and the display quality may be improved.

It is understandable that, when the film layer where the data line S is located has insufficient space, a part of the first sub-line LZ1, the second sub-line LZ2, the third sub-line LZ3, and the fourth sub-line LZ4 may be arranged in a different layer from the data line S. The present embodiment does not impose any specific limitation on the layout film layers of the first sub-wire LZ1, the second sub-wire LZ2, the third sub-wire LZ3, and the fourth sub-wire LZ4, provided that there is sufficient spacing between layout structures to avoid short circuits.

Optionally, in an example, the first connection portion, the second connection portion, the third connection portion, and the fourth connection portion are vias (not shown in FIGS. 21-23). When the fifth data line S5 is close to the transistor to be connected to the first sub-pixel circuit 1011 in the first pixel-circuit column 10A1, a via may be directly drilled below the fifth data line S5 in a direction perpendicular to the plane where the display panel is located. The fifth data line S5 may be electrically connected to the first sub-pixel circuit 1011 in the first pixel-circuit column 10A1 through the via without a connection sub-line.

When the sixth data line S6 is close to the transistor to be connected to the second pixel circuit 102 in the second pixel-circuit column 10A2, a via may be directly drilled below the sixth data line S6 in the direction perpendicular to the plane where the display panel is located. The sixth data line S6 may be electrically connected to the second pixel circuit 102 in the second pixel-circuit column 10A2 through the via without a connection sub-line.

When the seventh data line S7 is close to the transistor to be connected to the third pixel circuit 103 in the third pixel-circuit column 10A3, a via may be directly drilled below the seventh data line S7 in the direction perpendicular to the plane where the display panel is located. The seventh data line S7 may be electrically connected to the third pixel circuit 103 in the third pixel-circuit column 10A3 through the via without a connection sub-line.

When the eighth data line S8 is close to the transistor to be connected to the fourth sub-pixel circuit 1042 in the fourth pixel-circuit column 10A4, a via may be directly drilled below the eighth data line S8 in a direction perpendicular to the plane where the display panel is located. The eighth data line S8 may be electrically connected to the fourth sub-pixel circuit 1042 in the fourth pixel-circuit column 10A4 through the via without a connection sub-line.

That is, in one embodiment, in the display panel, a via may be directly drilled in the direction perpendicular to the plane where the display panel is located to realize the electrical connection between the data line of a current column and the pixel circuit of a corresponding current column. Accordingly, the number of signal lines in the panel may be reduced, the manufacturing process may be simplified, the pixel arrangement density may be increased, and the display quality may be improved.

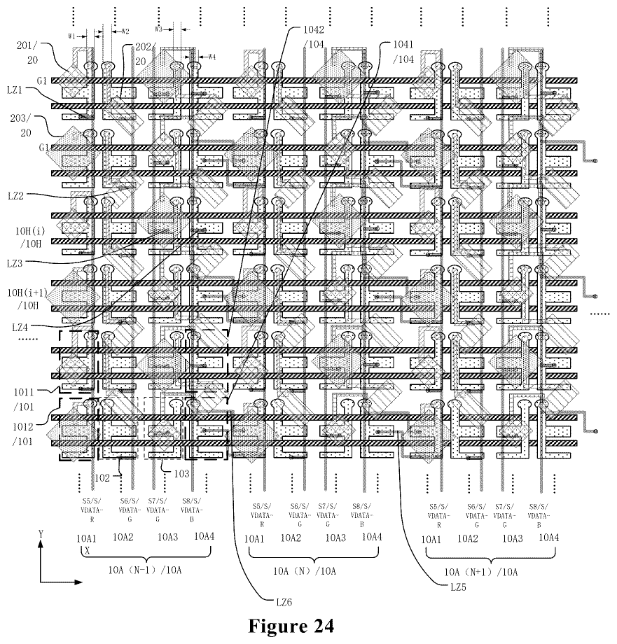

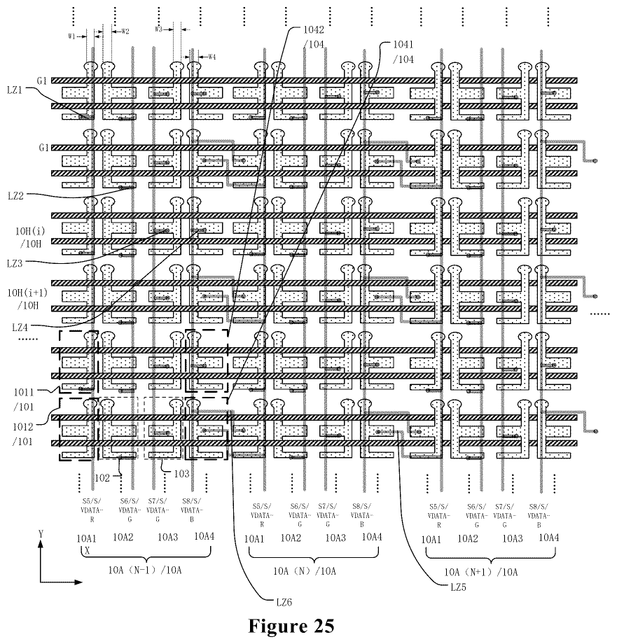

FIG. 24 illustrates a partially enlarged schematic diagram of the corresponding area of the plurality of pixel-circuit column groups in FIG. 21, consistent with the disclosed embodiments of the present disclosure. FIG. 25 illustrates a schematic diagram of a corresponding layout of the pixel circuit and the data line in FIG. 24, consistent with the disclosed embodiments of the present disclosure. To clearly illustrate the structure, the light-emitting element in FIG. 25 is omitted, and FIG. 24 and FIG. 25 are filled with different transparency degrees. In some embodiments, referring to FIGS. 21-25, along the first direction X, the display panel includes an (N−1)-th pixel-circuit column group 10A(N−1), an N-th pixel-circuit column group 10A(N), and an (N+1)-th pixel-circuit column group 10A(N+1), where N is a positive integer greater than or equal to 2.

The fifth data line S5 corresponding to the N-th pixel-circuit column group 10A(N) may be also electrically connected to the third sub-pixel circuit 1041 of the fourth pixel-circuit column 10A4 in the (N−1)-th pixel-circuit column group 10A(N−1). The eighth data line S8 corresponding to the N-th pixel-circuit column group 10A(N) may be also electrically connected to the second sub-pixel circuit 1012 of the first pixel-circuit column 10A1 in the (N+1)-th pixel-circuit column group 10A(N+1).

Optionally, the fifth data line S5 may be electrically connected to the first sub-pixel circuit 1011 in the first pixel-circuit column 10A1 through the first sub-line LZ1. The sixth data line S6 may be electrically connected to the second pixel circuit 102 in the second pixel-circuit column 10A2 through the second sub-line LZ2. The seventh data line S7 may be electrically connected to the third pixel circuit 103 in the third pixel-circuit column 10A3 through the third sub-line LZ3. The eighth data line S8 may be electrically connected to the fourth sub-pixel circuit 1042 in the fourth pixel-circuit column 10A4 through the fourth sub-line LZ4.

The fifth data line S5 corresponding to the N-th pixel-circuit column group 10A(N) may be electrically connected to the third sub-pixel circuit 1041 of the fourth pixel-circuit column 10A4 in the (N−1)-th pixel-circuit column group 10A(N−1) through the fifth sub-line LZ5. The eighth data line S8 corresponding to the N-th pixel-circuit column group 10A(N) may be electrically connected to the second sub-pixel circuit 1012 of the first pixel-circuit column 10A1 in the (N+1)-th pixel-circuit column group 10A(N+1) through the sixth sub-line LZ6. The length of the fifth sub-line LZ5 may be greater than the length of the first sub-line LZ1; and/or the length of the sixth sub-line LZ6 may be greater than the length of the fourth sub-line LZ4.

In one embodiment, the light-emitting elements 20 driven by a plurality of pixel circuits 10 electrically connected to a same data line S have a same color. The fifth data line S5 is only configured to provide the data voltage signal VDATA-R for the pixel circuit 10 electrically connected to the first color light-emitting element 201. The sixth data line S6 is only configured to provide the data voltage signal VDATA-G for the pixel circuit 10 electrically connected to the second color light-emitting element 202. The seventh data line S7 is only configured to provide the data voltage signal VDATA-G for the pixel circuit 10 electrically connected to the second color light-emitting element 202. The eighth data line S8 is only configured to provide the data voltage signal VDATA-B to the pixel circuit 10 electrically connected to the third color light-emitting element 203.

As such, the fifth data line S5 corresponding to the N-th pixel-circuit column group 10A(N) also needs to be electrically connected to the third sub-pixel circuit 1041 of the fourth pixel-circuit column 10A4 in a previous adjacent pixel-circuit column group, that is, the (N−1)-th pixel-circuit column group 10A(N−1). The eighth data line S8 corresponding to the N-th pixel-circuit column group 10A(N) also needs to be electrically connected to the second sub-pixel circuit 1012 of the first pixel-circuit column 10A1 in a next adjacent pixel-circuit column group, that is, the (N+1)-th pixel-circuit column group 10A(N+1).

Accordingly, the second sub-pixel circuit 1012 and the first sub-pixel circuit 1011 of the first pixel-circuit column 10A1 may drive light-emitting elements of different colors and may be connected to different data lines S. The third sub-pixel circuit 1041 and the fourth sub-pixel circuit 1042 of the fourth pixel-circuit column 10A4 may drive light-emitting elements of different colors and may be connected to different data lines S. In this way, the problems of color deviation may be eased. In addition, the light-emitting elements 20 driven by a plurality of pixel circuits 10 electrically connected to a same data line S may have a same color, and the driving power consumption may be reduced.

Optionally, in one embodiment, as shown in FIGS. 24 and 25, the length of the fifth sub-line LZ5 is greater than the length of the first sub-line LZ1, and/or, the length of the sixth sub-line LZ6 is greater than the length of the fourth sub-line LZ4. Since the fifth sub-line LZ5 needs to be extended from the fifth data line S5 corresponding to the N-th pixel-circuit column group 10A(N) to the third sub-pixel circuit 1041 of the fourth pixel-circuit column 10A4 in the adjacent (N−1)-th pixel-circuit column group 10A(N−1), and the first sub-line LZ1 is only configured to connect the data line of a current column with the pixel circuit of a corresponding current column, the fifth sub-line LZ5 may be relatively long, and the length of the fifth sub-line LZ5 may be greater than the length of the first sub-line LZ1.

Similarly, since the sixth sub-line LZ6 needs to be extended from the eighth data line S8 corresponding to the N-th pixel-circuit column group 10A (N) to the second sub-pixel circuit 1012 of the first pixel-circuit column 10A1 in the adjacent (N+1)-th pixel-circuit column group 10A (N+1), and the fourth sub-line LZ4 is only configured to connect the data line of a current column with the pixel circuit of a corresponding current column, the sixth sub-line LZ6 may be relatively long, and the length of the sixth sub-line LZ6 may be greater than the length of the fourth sub-line LZ4. Accordingly, by increasing the length of the sub-line, the electrical connection between the data lines S corresponding to different pixel-circuit column groups 10A and non-current columns may be realized. In addition, the light-emitting elements 20 driven by a plurality of pixel circuits 10 electrically connected to a same data line S may have a same color, and the driving power consumption may be reduced.

Optionally, though the first sub-line LZ1, the second sub-line LZ2, the third sub-line LZ3, and the fourth sub-line LZ4 each are relatively short, the first sub-line LZ1, the second sub-line LZ2, the third sub-line LZ3, and the fourth sub-line LZ4 may be on a same layer as the data line S. That is, the first sub-line LZ1, the second sub-line LZ2, the third sub-line LZ3, and the fourth sub-line LZ4 may be directly pulled out from the data line S to achieve the electrical connection effect with the pixel circuit 10. The number of vias drilled, when the first sub-line LZ1, the second sub-line LZ2, the third sub-line LZ3, and the fourth sub-line LZ4 are in different layers from the data line S, may be reduced, and the display quality may thus be improved.

The fifth sub-wire LZ5 is relatively long, and the length of the fifth sub-wire LZ5 is greater than the length of the first sub-wire LZ1. The sixth sub-wire LZ6 is relatively long, and the length of the sixth sub-wire LZ6 is greater than the length of the fourth sub-wire LZ4. As such, at least part of the fifth sub-lines LZ5 are in a different layer from the data line S, or, at least part of the sixth sub-lines LZ6 are in a different layer from the data line S. In this case, other conductive film layers other than the film layer where the data line S is located may be drilled for routing. Accordingly, short circuit problems between different lines caused by excessive routing in the film layer where the data line S is located may be avoided, and product yield may be improved.

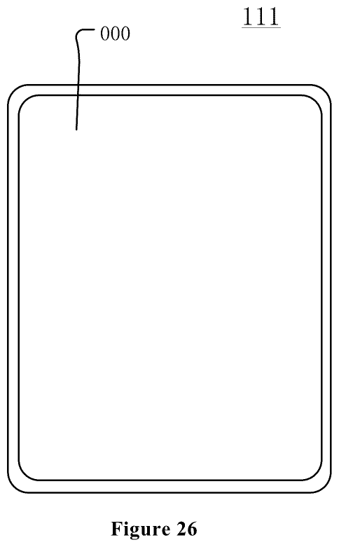

The present disclosure also provides a display device. FIG. 26 illustrates a schematic diagram of a planar structure of a display device consistent with the disclosed embodiments of the present disclosure. Referring to FIG. 26, the display device 111 includes the display panel 000 provided by the present invention. FIG. 26 takes a mobile phone as an example. It is understandable that the display device 111 may be a computer, a television, a vehicle-mounted display device or other display device with a display function, and the present invention does not limit a specific display device. The display device 111 provided by the present disclosure has the beneficial effects of the display panel 000 provided by the present disclosure. For details, reference may be made to specific descriptions of the display panel 000 in the present disclosure, which will not be elaborated here.

As disclosed, the technical solutions of the present disclosure have the following advantages.

In the present disclosure, the first pixel-circuit column includes a plurality of first pixel circuits, and the second pixel-circuit column includes a plurality of second pixel circuits. The channel width of the first transistor of the first pixel circuit may be different from the channel width of the first transistor of the second pixel circuit. The first pixel circuit may drive the first color light-emitting element or the third color light-emitting element, and the second pixel circuit may drive the second color light-emitting element. The third pixel-circuit column includes a plurality of third pixel circuits, and the fourth pixel-circuit column includes a plurality of fourth pixel circuits. The channel width of the first transistor of the third pixel circuit may be different from the channel width of the first transistor of the fourth pixel circuit. The channel width of the first transistor of the third pixel circuit may be same as the channel width of the first transistor of the first pixel circuit. The channel width of the first transistor of the fourth pixel circuit may be same as the channel width of the first transistor of the second pixel circuit. The color of the light-emitting element driven by the third pixel circuit may be different from the color of the light-emitting element driven by the first pixel circuit. The third pixel circuit may drive the second color light-emitting element. The color of the light-emitting element driven by the fourth pixel circuit may be different from the color of the light-emitting element driven by the second pixel circuit. The fourth pixel circuit may drive the third color light-emitting element or the first color light-emitting element. As such, the color deviation of the light-emitting area corresponding to the third pixel circuit and the fourth pixel circuit may be neutralized with the color deviation of the light-emitting area corresponding to the first pixel circuit and the second pixel circuit. Accordingly, for the overall visual effect, the color deviation and mura problems may be eased, and the display quality may be improved.

The present disclosure may have only minor changes to the layout structure of the display panel. There is no need to change the layout structure of the pixel circuit and the layout structure of the light-emitting element, nor is there any need to adopt a complex brightness compensation method. It is only necessary that in the pixel-circuit column group including four adjacent pixel-circuit columns adjacent in the first direction, the first pixel circuit drives the first color light-emitting element or the third color light-emitting element, the second pixel circuit drives the second color light-emitting element, the third pixel circuit drives the second color light-emitting element, and the fourth pixel circuit drives the third color light-emitting element or the first color light-emitting element. That is, by changing the color of the light-emitting element driven by the third pixel circuit and the color of the light-emitting element driven by the fourth pixel circuit, the display color deviation problem may be eased. The structure and fabrication process of the display panel may be relatively simple, and the manufacturing efficiency of the display panel may be improved.

The embodiments disclosed herein are exemplary only and not limiting the scope of the present disclosure. Various combinations, alternations, modifications, equivalents, or improvements to the technical solutions of the disclosed embodiments may be obvious to those skilled in the art. Without departing from the spirit and scope of this disclosure, such combinations, alternations, modifications, equivalents, or improvements to the disclosed embodiments are encompassed within the scope of the present disclosure.

What is claimed is:

1. A display panel, comprising a plurality of pixel circuits, a plurality of pixel-circuit column groups sequentially arranged along a first direction, and a plurality of light-emitting elements, wherein:
a pixel circuit of the plurality of pixel circuits includes a driving transistor and a first transistor electrically connected to the driving transistor;
the plurality of pixel circuits at least includes a first pixel circuit, a second pixel circuit, a third pixel circuit, and a fourth pixel circuit;
a pixel-circuit column group of the plurality of pixel-circuit column groups includes a first pixel-circuit column, a second pixel-circuit column, a third pixel-circuit column, and a fourth pixel-circuit column;
the first pixel-circuit column includes a plurality of the first pixel circuits, the second pixel-circuit column includes a plurality of the second pixel circuits, the third pixel-circuit column includes a plurality of the third pixel circuits, and the fourth pixel-circuit column includes a plurality of the fourth pixel circuits;
a channel width of the first transistor of the first pixel circuit is different from a channel width of the first transistor of the second pixel circuit, a channel width of the first transistor of the third pixel circuit is different from a channel width of the first transistor of the fourth pixel circuit, the channel width of the first transistor of the first pixel circuit is equal to the channel width of the first transistor of the third pixel circuit, and the channel width of the first transistor of the second pixel circuit is equal to the channel width of the first transistor of the fourth pixel circuit; and
the plurality of light-emitting elements includes a first color light-emitting element, a second color light-emitting element, and a third color light-emitting element, wherein the first pixel circuit drives the first color light-emitting element or the third color light-emitting element, the second pixel circuit drives the second color light-emitting element, the third pixel circuit drives the second color light-emitting element, and the fourth pixel circuit drives the third color light-emitting element or the first color light-emitting element.

2. The display panel according to claim 1, wherein:
the channel width of the first transistor of the first pixel circuit is W1, and the channel width of the first transistor of the second pixel circuit is W2, wherein |W1-W2|≤0.1 μm; and
the channel width of the first transistor of the third pixel circuit is W3, and the channel width of the first transistor of the fourth pixel circuit is W4, wherein |W3-W4|≤0.1 μm.

3. The display panel according to claim 1, wherein:
the channel width of the first transistor of the first pixel circuit is smaller than the channel width of the first transistor of the second pixel circuit; and
the channel width of the first transistor of the third pixel circuit is smaller than the channel width of the first transistor of the fourth pixel circuit.

4. The display panel according to claim 1, wherein:
the first color light-emitting element is one of a red light-emitting element or a blue light-emitting element, and the third color light-emitting element is an other of the red light-emitting element or the blue light-emitting element; and
the second color light-emitting element is a green light-emitting element.

5. The display panel according to claim 1, wherein:
the first transistor is electrically connected between a gate and a first electrode of the driving transistor, and the first transistor is an N-type transistor.

6. The display panel according to claim 1, wherein:
in the first direction, the first pixel circuit of the first pixel-circuit column and the second pixel circuit of the second pixel-circuit column are symmetrical, and the third pixel circuit of the third pixel-circuit column and the fourth pixel circuit of the fourth pixel-circuit column are symmetrical.

7. The display panel according to claim 1, further comprising a plurality of light-emitting element column groups sequentially arranged along the first direction, wherein:
a light-emitting element column group of the plurality of light-emitting element column groups includes a first light-emitting element column, a second light-emitting element column, a third light-emitting element column and a fourth light-emitting element column that are sequentially arranged along the first direction;
along a second direction, the first light-emitting element column includes a plurality of the first color light-emitting elements and the third color light-emitting elements that are alternately arranged, the second light-emitting element column includes a plurality of the second color light-emitting elements, the third light-emitting element column includes a plurality of the third color light-emitting elements and the first color light-emitting elements that are alternately arranged, and the fourth light-emitting element column includes a plurality of the second color light-emitting elements, wherein the first direction and the second direction intersect on a plane parallel to the display panel;
a plurality of the pixel circuits is arranged along the first direction, forming a pixel circuit row; and
along the second direction, in an i-th pixel circuit row of the pixel circuit row, the first pixel circuit is electrically connected to the first color light-emitting element of the first light-emitting element column, the second pixel circuit is electrically connected to the second color light-emitting element of the second light-emitting element column, the third pixel circuit is electrically connected to the second color light-emitting element of the fourth light-emitting element column, and the fourth pixel circuit is electrically connected to the third color light-emitting element of the third light-emitting element column, wherein i is a positive integer.

8. The display panel according to claim 7, wherein:
along the second direction Y, in an (i+1)-th pixel circuit row of the pixel circuit row, the first pixel circuit is electrically connected to the third color light-emitting element of the first light-emitting element column, the second pixel circuit is electrically connected to the second color light-emitting element of the second light-emitting element column, the third pixel circuit is electrically connected to the second color light-emitting element of the fourth light-emitting element column, and the fourth pixel circuit is electrically connected to the first color light-emitting element of the third light-emitting element column.

9. The display panel according to claim 7, wherein:
the first pixel circuit is electrically connected to the first color light-emitting element of the first light-emitting element column through a first connection line;
the second pixel circuit is electrically connected to the second color light-emitting element of the second light-emitting element column through a second connection line;
the third pixel circuit is electrically connected to the second color light-emitting element of the fourth light-emitting element column through a third connection line; and
the fourth pixel circuit is electrically connected to the third color light-emitting element of the third light-emitting element column through a fourth connection line.

10. The display panel according to claim 9, wherein:
a length of one or more of the first connection line and the second connection line is less than a length of one or more of the third connection line and the fourth connection line.

11. The display panel according to claim 9, further comprising a substrate, a driving array layer, and an anode layer, wherein:
the anode layer is disposed on a side of the driving array layer away from the substrate;
the driving array layer includes the plurality of pixel circuits;
the anode layer includes a plurality of anodes, wherein a light-emitting element of the plurality of light-emitting elements is electrically connected to a pixel circuit of the plurality of pixel circuits through an anode of the plurality of anodes; and
one or more of the first connection line, the second connection line, the third connection line, and the fourth connection line is located at the anode layer, or one or more of the first connection line, the second connection line, the third connection line, and the fourth connection line is located in the driving array layer.

12. The display panel according to claim 11, wherein:
the driving array layer includes a first metal layer, and no other conductive layer is disposed between the first metal layer and the anode layer; or
at least a part of the third connection lines is disposed on the first metal layer, or at least a part of the fourth connection lines is disposed on the first metal layer.

13. The display panel according to claim 7, further comprising a plurality of data lines,
wherein:
the plurality of data lines includes a first data line, a second data line, a third data line, and a fourth data line arranged along the first direction, wherein the first data line is electrically connected to the first pixel circuit, the second data line is electrically connected to the second pixel circuit, the third data line is electrically connected to the third pixel circuit, and the fourth data line is electrically connected to the fourth pixel circuit; and
along the first direction, the second data line and the third data line are adjacently arranged with a spacing of D1, the first data line and the second data line are adjacently arranged with a spacing of D2, and the third data line and the fourth data line are adjacently arranged with a spacing of D3, wherein D2>D1, and D3>D1.

14. The display panel according to claim 13, further comprising a non-display area, wherein:
the non-display area includes a plurality of first binding pads, a plurality of second binding pads, a plurality of third binding pads, and a plurality of fourth binding pads, wherein a first binding pad of the plurality of first binding pads, a second binding pad of the plurality of second binding pads, a third binding pad of the plurality of third binding pads, and a fourth binding pad of the plurality of fourth binding pads are sequentially arranged along the first direction;
the first data line is electrically connected to the first binding pad through a first fan-out line, the second data line is electrically connected to the second binding pad through a second fan-out line, the third data line is electrically connected to the fourth binding pad through a third fan-out line, and the fourth data line is electrically connected to the third binding pad through a fourth fan-out line; and
the third fan-out line and the fourth fan-out line are arranged at different layers, and an orthographic projection of the third fan-out line on a plane where the display panel is located overlaps with an orthographic projection of the fourth fan-out line on the plane where the display panel is located.

15. The display panel according to claim 7, further comprising a plurality of data lines, wherein:
a data line of the plurality of data lines is electrically connected to a pixel circuit of the plurality of pixel circuits; and
the light-emitting elements driven by a plurality of the pixel circuits electrically connected to a same data line of the plurality of data lines have a same color.

16. The display panel according to claim 15, wherein:
the plurality of data lines includes a fifth data line, a sixth data line, a seventh data line and an eighth data line that are arranged along the first direction;
the fifth data line is configured to provide a data voltage signal to the pixel circuit electrically connected to the first color light-emitting element, the sixth data line is configured to provide a data voltage signal for the pixel circuit electrically connected to the second color light-emitting element, the seventh data line is configured to provide a data voltage signal for the pixel circuit electrically connected to the second color light-emitting element, and the eighth data line is configured to provide a data voltage signal to the pixel circuit electrically connected to the third color light-emitting element;
the plurality of first pixel circuits of the first pixel-circuit column includes a first sub-pixel circuit and a second sub-pixel circuit, wherein the first sub-pixel circuit is electrically connected to the first color light-emitting element of the first light-emitting element column, and the second sub-pixel circuit is electrically connected to the third color light-emitting element of the first light-emitting element column;
the fifth data line is electrically connected to the first sub-pixel circuit in the first pixel-circuit column;
the sixth data line is electrically connected to the second pixel circuit in the second pixel-circuit column;
the seventh data line is electrically connected to the third pixel circuit in the third pixel-circuit column;
the plurality of fourth pixel circuits of the fourth pixel-circuit column includes a third sub-pixel circuit and a fourth sub-pixel circuit, wherein the third sub-pixel circuit is electrically connected to the first color light-emitting element of the third light-emitting element column, and the fourth sub-pixel circuit is electrically connected to the third color light-emitting element of the third light-emitting element column; and
the eighth data line is electrically connected to the fourth sub-pixel circuit in the fourth pixel-circuit column.

17. The display panel according to claim 16, wherein:
the fifth data line is electrically connected to the first sub-pixel circuit in the first pixel-circuit column through a first sub-line;
the sixth data line is electrically connected to the second pixel circuit in the second pixel-circuit column through a second sub-line;
the seventh data line is electrically connected to the third pixel circuit in the third pixel-circuit column through a third sub-line;
the eighth data line is electrically connected to the fourth sub-pixel circuit in the fourth pixel-circuit column through a fourth sub-line; and
one or more of the first sub-line, the second sub-line, the third sub-line, and the fourth sub-line is in a same layer as the plurality of data lines.

18. The display panel according to claim 16, wherein:
along the first direction, the display panel includes an (N−1)-th pixel-circuit column group, an N-th pixel-circuit column group, and an (N+1)-th pixel-circuit column group, wherein N is a positive integer greater than or equal to 2;
the fifth data line corresponding to the N-th pixel-circuit column group is further electrically connected to the third sub-pixel circuit of the fourth pixel-circuit column in the (N−1)-th pixel-circuit column group; and
the eighth data line corresponding to the N-th pixel-circuit column group is further electrically connected to the second sub-pixel circuit of the first pixel-circuit column in the (N+1)-th pixel-circuit column group.

19. The display panel according to claim 18, wherein:
the fifth data line is electrically connected to the first sub-pixel circuit in the first pixel-circuit column through a first sub-line;
the sixth data line is electrically connected to the second pixel circuit in the second pixel-circuit column through a second sub-line;
the seventh data line is electrically connected to the third pixel circuit in the third pixel-circuit column through a third sub-line;
the eighth data line is electrically connected to the fourth sub-pixel circuit in the fourth pixel-circuit column through a fourth sub-line;
the fifth data line corresponding to the N-th pixel-circuit column group is electrically connected to the third sub-pixel circuit of the fourth pixel-circuit column in the (N−1)-th pixel-circuit column group through a fifth sub-line;
the eighth data line corresponding to the N-th pixel-circuit column group is electrically connected to the second sub-pixel circuit of the first pixel-circuit column in the (N+1)-th pixel-circuit column group through a sixth sub-line; and
a length of the fifth sub-line is greater than a length of the first sub-line, and/or a length of the sixth sub-line is greater than a length of the fourth sub-line.

20. A display device, comprising a display panel, wherein the display panel includes a plurality of pixel circuits, a plurality of pixel-circuit column groups sequentially arranged along a first direction, and a plurality of light-emitting elements, wherein:
a pixel circuit of the plurality of pixel circuits includes a driving transistor and a first transistor electrically connected to the driving transistor;
the plurality of pixel circuits at least includes a first pixel circuit, a second pixel circuit, a third pixel circuit, and a fourth pixel circuit;
a pixel-circuit column group of the plurality of pixel-circuit column groups includes a first pixel-circuit column, a second pixel-circuit column, a third pixel-circuit column, and a fourth pixel-circuit column;
the first pixel-circuit column includes a plurality of the first pixel circuits, the second pixel-circuit column includes a plurality of the second pixel circuits, the third pixel-circuit column includes a plurality of the third pixel circuits, and the fourth pixel-circuit column includes a plurality of the fourth pixel circuits;
a channel width of the first transistor of the first pixel circuit is different from a channel width of the first transistor of the second pixel circuit, a channel width of the first transistor of the third pixel circuit is different from a channel width of the first transistor of the fourth pixel circuit, the channel width of the first transistor of the first pixel circuit is equal to the channel width of the first transistor of the third pixel circuit, and the channel width of the first transistor of the second pixel circuit is equal to the channel width of the first transistor of the fourth pixel circuit; and
the plurality of light-emitting elements includes a first color light-emitting element, a second color light-emitting element, and a third color light-emitting element, wherein the first pixel circuit drives the first color light-emitting element or the third color light-emitting element, the second pixel circuit drives the second color light-emitting element, the third pixel circuit drives the second color light-emitting element, and the fourth pixel circuit drives the third color light-emitting element or the first color light-emitting element.
